(19) United States
(12) Patent Application Publication
(10) Pub. No.: US 2025/0129308 A1
(43) Pub. Date: Apr. 24, 2025

(54) SEMICONDUCTOR TREATMENT LIQUID, TREATMENT METHOD FOR OBJECT TO BE TREATED, AND MANUFACTURING METHOD OF ELECTRONIC DEVICE

(71) Applicant: FUJIFILM CORPORATION, Tokyo (JP)

(72) Inventors: Yuta Shigenoi, Shizuoka (JP); Tetsuya Kamimura, Shizuoka (JP); Atsushi Mizutani, Shizuoka (JP); Shimpei Yamada, Shizuoka (JP)

(21) Appl. No.: 19/005,399

(22) Filed: Dec. 30, 2024

Related U.S. Application Data
(63) Continuation of application No. PCT/JP2023/022277, filed on Jun. 15, 2023.

(30) Foreign Application Priority Data
Jul. 13, 2022 (JP) 2022-112332

(51) Int. Cl. C11D 3/28; C11D 3/00; C11D 3/30; H01L 21/02

(52) U.S. Cl. CPC C11D 3/28; C11D 3/0047; C11D 3/30; H01L 21/02074; C11D 2111/22

(57) ABSTRACT

An object of the present invention is to provide a semiconductor treatment liquid which has excellent anticorrosion properties against at least one metal selected from the group consisting of Cu and Co in a case of being brought into contact with an object containing the metal, and also has excellent cleanability for organic residues on a surface of the object to be treated; and to provide a treatment method for an object to be treated and a manufacturing method of an electronic device. The treatment liquid of the present invention contains a purine compound and an amine compound, in which the purine compound includes at least one selected from the group consisting of purine and a purine derivative, the amine compound includes at least two of one amine compound A and one or two or more amine compounds B different from the amine compound A, the amine compound A is a tertiary amine compound, and a mass ratio of a content of the purine compound to a content of the amine compound is 0.0001 to 0.1.

### CROSS-REFERENCE TO RELATED APPLICATIONS

This application is a Continuation of PCT International Application No. PCT/JP2023/022277 filed on Jun. 15, 2023, which claims priority under 35 U.S.C. § 119 (a) to Japanese Patent Application No. 2022-112332 filed on Jul. 13, 2022. The above applications are hereby expressly incorporated by reference, in their entirety, into the present application.

### BACKGROUND OF THE INVENTION

### 1. Field of the Invention

The present invention relates to a semiconductor treatment liquid, a treatment method for an object to be treated, and a manufacturing method of an electronic device.

### 2. Description of the Related Art

A semiconductor element is manufactured by forming a resist film on a laminate having, on a substrate, a metal film serving as a wiring line material, an etching stop layer, and an interlayer insulating layer, and performing a photolithography step. In the photolithography step, a method of etching or removing foreign substances on a surface of the substrate using a treatment liquid which dissolves a metal and/or an organic substance has been widely known.

In addition, in manufacturing of the semiconductor element, a chemical mechanical polishing (CMP) treatment in which a surface of a semiconductor substrate having a metal wire film, a barrier metal, an insulating film, or the like is flattened using a polishing slurry containing polishing fine particles (for example, silica and alumina) or the like may be carried out.

In the CMP treatment, the polishing fine particles to be used in the CMP treatment, a polished wiring line metal film, and/or a metal component derived from the barrier metal or the like easily remain on the surface of the semiconductor substrate after polishing. Therefore, after the CMP treatment, a cleaning step of removing these residues using a treatment liquid is generally performed.

As described above, in a semiconductor manufacturing process, the treatment liquid is used for treatments such as removal of unnecessary metal-containing substances, resist, and residues on the substrate. Hereinafter, such a treatment liquid used in the manufacturing process of the semiconductor element is also referred to as a semiconductor treatment liquid.

As the treatment liquid, for example, JP2018-507540A discloses a composition which is suitable for removing contaminants from a semiconductor wafer after chemical mechanical polishing, the composition containing one or more quaternary ammonium hydroxide compounds in an effective amount for adjusting a pH of the composition to approximately 10 to approximately 14, one or more organic amine compounds, a metal inhibitor, and water.

### SUMMARY OF THE INVENTION

As a result of studies, the present inventors have found that the composition disclosed in JP2018-507540A cannot achieve both anticorrosion properties against Cu and Co and cleanability for organic residues on a surface of an object to be treated, and further improvement is required.

Therefore, an object of the present invention is to provide a semiconductor treatment liquid which has excellent anticorrosion properties against at least one metal selected from the group consisting of Cu and Co in a case of being brought into contact with an object containing the metal, and also has excellent cleanability for organic residues on a surface of the object to be treated.

Another object of the present invention is to provide a treatment method for an object to be treated, using the treatment liquid, and a manufacturing method of an electronic device.

The present inventors have conducted intensive studies to achieve the above-described objects, and as a result, they have found that the objects can be achieved by the following configurations.

[1] A semiconductor treatment liquid comprising:
a purine compound; and
an amine compound,
in which the purine compound includes at least one selected from the group consisting of purine and a purine derivative,
the amine compound includes one amine compound A and one or two or more amine compounds B different from the amine compound A,
the amine compound A is a tertiary amine compound, and
a mass ratio of a content of the purine compound to a content of the amine compound is 0.0001 to 0.1.

[2] The semiconductor treatment liquid according to [1],
in which the amine compound A is one selected from the group consisting of a compound represented by Formula (A1) described later and a compound represented by Formula (A2) described later.

[3] The semiconductor treatment liquid according to [1] or [2],
in which a pH is 10.0 to 14.0.

[4] The semiconductor treatment liquid according to any one of [1] to [3],
in which the purine compound includes at least one selected from the group consisting of a compound represented by Formula (C5) described later and a compound represented by Formula (C7) described later.

[5] The semiconductor treatment liquid according to any one of [1] to [4],
in which at least one of the one or two or more amine compounds B is a tertiary amine compound.

[6] The semiconductor treatment liquid according to any one of [1] to [5],
in which at least one of the one or two or more amine compounds B is an amine compound having three or more nitrogen atoms.

[7] The semiconductor treatment liquid according to any one of [1] to [6],
in which at least one of the one or two or more amine compounds B is an amine compound having three or more nitrogen atoms.

[8] The semiconductor treatment liquid according to any one of [1] to [7],
in which a pKa of the amine compound A is 11.0 to 16.0.

[9] The semiconductor treatment liquid according to any one of [1] to [8],
in which a molecular weight of the amine compound A is 100 to 160.

[10] The semiconductor treatment liquid according to any one of [1] to [9],
in which the amine compound A has 6 to 9 carbon atoms.

[11] The semiconductor treatment liquid according to any one of [1] to [10],
in which the purine compound includes at least one selected from the group consisting of adenine, 6-benzyladenine, kinetin, dimethyladenine, methyladenine, xanthine, and adenosine.

[12] The semiconductor treatment liquid according to any one of [1] to [11],
in which the semiconductor treatment liquid is used as a cleaning liquid.

[13] The semiconductor treatment liquid according to any one of [1] to [12],
in which the semiconductor treatment liquid is used for an object which has been subjected to a chemical mechanical polishing treatment.

[14] The semiconductor treatment liquid according to any one of [1] to [13],
in which the semiconductor treatment liquid is used for an object containing at least one metal selected from the group consisting of Cu and Co.

[15] The semiconductor treatment liquid according to any one of [1] to [14],
in which the semiconductor treatment liquid is used for an object containing at least one metal selected from the group consisting of Cu and Co, which has been subjected to a chemical mechanical polishing treatment.

[16] A treatment method for an object to be treated, comprising:
a step of bringing an object containing at least one metal selected from the group consisting of Cu and Co, which has been subjected to a chemical mechanical polishing treatment, into contact with the semiconductor treatment liquid according to any one of [1] to [15].

[17] A manufacturing method of an electronic device, comprising:
the treatment method for an object to be treated according to [16].

According to the present invention, it is possible to provide a semiconductor treatment liquid which has excellent anticorrosion properties against at least one metal selected from the group consisting of Cu and Co in a case of being used for an object containing the metal, and also has excellent cleanability for organic residues on a surface of the object to be treated.

In addition, according to the present invention, it is possible to provide a treatment method for an object to be treated, using the treatment liquid, and a manufacturing method of an electronic device.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

In the present specification, numerical ranges represented by “to” include numerical values before and after “to” as lower limit values and upper limit values.

In addition, in the present specification, in a case where there are two or more components corresponding to a certain component, “content” of such a component means the total content of the two or more components.

In the present specification, “total mass of components in the treatment liquid excluding a solvent” means the total mass of all components contained in the treatment liquid other than a solvent such as water and an organic solvent.

In the present specification, in a case of a plurality of substituents, linking groups, and the like (hereinafter, referred to as a substituent and the like) represented by specific reference numeral, or in a case of simultaneously defining a plurality of the substituent and the like, it means that each of the substituent and the like may be the same as or different with each other. The same applies to the definition of the number of substituents and the like.

A bonding direction of divalent groups cited in the present specification is not limited unless otherwise specified. For example, in a case where Y in a compound represented by Formula “X—Y—Z” is —COO—, Y may be —CO—O— or —O—CO—. In addition, the above-described compound may be “X—CO—O—Z” or “X—O—CO—Z”.

In the present specification, “ppm” means “parts-per-million (10⁻⁶)”, and “ppb” means “parts-per-billion (10⁻⁹)”.

In the present specification, “weight-average molecular weight” means a weight-average molecular weight in terms of polyethylene glycol measured by gel permeation chromatography (GPC).

### [Treatment Liquid]

Hereinafter, each component contained in the semiconductor treatment liquid according to the embodiment of the present invention will be described in detail.

The semiconductor treatment liquid (hereinafter, also simply referred to as “treatment liquid”) according to the embodiment of the present invention contains a purine compound and an amine compound, in which the purine compound includes at least one selected from the group consisting of purine and a purine derivative, the amine compound includes one amine compound A which is a tertiary amine compound, and one or two or more amine compounds B different from the amine compound A, and a mass ratio of a content of the purine compound to a content of the amine compound is 0.0001 to 0.1.

The reason why the treatment liquid having the above-described configuration can achieve the object of the present invention is not necessarily clear, but the present inventors speculate as follows.

The mechanism by which the effect is obtained is not limited by the following supposition. In other words, even in a case where an effect is obtained by a mechanism other than the following, it is included in the scope of the present invention.

Since the treatment liquid contains at least two kinds of amine compounds, the treatment liquid has excellent cleanability for organic residues on a surface of an object to be treated. On the other hand, since the amine compound A is a tertiary amine compound, basicity is appropriately adjusted, and since the treatment liquid contains a purine compound which functions as an anticorrosion agent for a predetermined metal, corrosion of the predetermined metal is suppressed, and as a result, excellent anticorrosion properties against the predetermined metal are exhibited. Furthermore, it is presumed that, by specifying the content ratio between the purine compound and the amine compound, in the semiconductor treatment liquid according to the embodiment of the present invention, both excellent anticorrosion properties against a predetermined metal and excellent cleanability for organic residues on the surface of an object to be treated are achieved.

Hereinafter, in the present specification, the cleanability of the semiconductor treatment liquid according to the embodiment of the present invention for organic residues on the surface of the object to be treated is also simply referred to as “cleanability”. In addition, the fact that at least one of the anticorrosion properties or the cleanability is more excellent is also referred to as “effect of the present invention is more excellent”.

### [Purine Compound]

The treatment liquid contains a purine compound. The purine compound includes at least one compound selected from the group consisting of purine and a purine derivative.

The purine compound preferably includes at least one selected from the group consisting of compounds represented by Formulae (C1) to (C4); more preferably includes at least one selected from the group consisting of compounds represented by Formulae (C5) to (C8); and still more preferably includes at least one selected from the group consisting of a compound represented by Formula (C5) and a compound represented by Formula (C7).

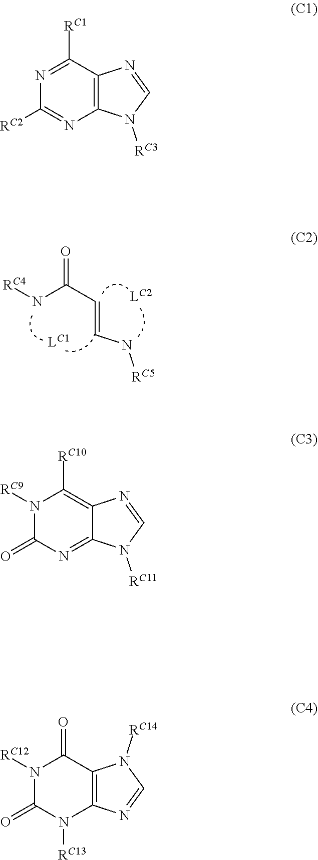

In Formula (C1), R^{C1} to R^{C3} each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent.

The above-described alkyl group may be linear, branched, or cyclic.

The number of carbon atoms in the above-described alkyl group is preferably 1 to 10, more preferably 1 to 5, and still more preferably 1 to 3.

Examples of the above-described sugar group include a group obtained by removing one hydroxy group from a sugar selected from the group consisting of a monosaccharide, a disaccharide, and a polysaccharide; and a group obtained by removing one hydroxy group from a monosaccharide is preferable.

Examples of the monosaccharides include a pentose such as ribose, deoxyribose, arabinose, or xylose, a triose, a tetrose, a hexose, and a heptose; and a pentose is preferable, ribose, deoxyribose, arabinose, or xylose is more preferable, and ribose or deoxyribose is still more preferable.

Examples of the disaccharides include sucrose, lactose, maltose, trehalose, turanose, and cellobiose.

Examples of the polysaccharides include glycogen, starch, and cellulose.

The above-described saccharides may be chain-like or cyclic, and are preferably cyclic.

Examples of the above-described cyclic saccharides include a furanose ring and a pyranose ring.

The polyoxyalkylene group-containing group which may have a substituent means a group containing, as a part of the group, a polyoxyalkylene group, which may have a substituent.

Examples of the polyoxyalkylene group constituting the polyoxyalkylene group-containing group include a polyoxyethylene group, a polyoxypropylene group, and a polyoxybutylene group; and a polyoxyethylene group is preferable.

Examples of the substituent contained in the alkyl group, amino group, sugar group, and polyoxyalkylene group-containing group described above include a hydrocarbon group such as an alkyl group which may have a substituent, an aryl group, and a benzyl group; a halogen atom such as a fluorine atom, a chlorine atom, and a bromine atom; an alkoxy group; a hydroxy group; an alkoxycarbonyl group such as a methoxycarbonyl group and an ethoxycarbonyl group; an acyl group such as an acetyl group, a propionyl group, and a benzoyl group; a cyano group; and a nitro group.

Examples of the substituent which may be contained in the above-described alkyl group which may have a substituent include the groups exemplified as the substituent, and more specific examples thereof include an aryl group and a heteroaryl group.

R^{C1} is preferably a hydrogen atom or an amino group which may have a substituent, and more preferably an amino group which may have a substituent.

Another suitable aspect of R^{C1} is preferably an alkyl group which may have a substituent, a thiol group, a hydroxy group, a halogen atom, a sugar group which may have a substituent, or a polyoxyalkylene group-containing group which may have a substituent.

R^{C2} is preferably a hydrogen atom or an alkyl group which may have a substituent, and more preferably a hydrogen atom.

R^{C3} is preferably a hydrogen atom, an alkyl group which may have a substituent, or a sugar group which may have a substituent, more preferably a hydrogen atom or a sugar group which may have a substituent, and still more preferably a hydrogen atom.

In Formula (C2), L^{C1} represents —CR^{C6}—N— or —C(═O)—NR^{C7}—, L^{C2} represents —N═CH— or —NR^{C8}—C(═O)—, and R^{C4} to R^{C8} each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent.

Examples of an aspect of each group represented by R^{C4} to R^{C8} include the above-described aspect of each group represented by R^{C1} to R^{C3} in Formula (C1).

R^{C4} and R^{C5} are preferably a hydrogen atom or an alkyl group which may have a substituent, and more preferably a hydrogen atom.

R^{C6} is preferably a hydrogen atom, an alkyl group which may have a substituent, or an amino group which may have a substituent, and more preferably a hydrogen atom.

L^{C1} is preferably —C(═O)—NR^{C7}—.

R^{C7} is preferably a hydrogen atom or an alkyl group which may have a substituent, and more preferably a hydrogen atom.

L^{C2} is preferably —N═CH—.

R^{C8} is preferably a hydrogen atom or an alkyl group which may have a substituent, and more preferably a hydrogen atom.

In Formula (C3), R^{C9} to R^{C11} each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent.

Examples of an aspect of each group represented by R^{C9} to R^{C11} include the above-described groups represented by R^{C1} to R^{C3} in Formula (C1).

R^{C9} is preferably a hydrogen atom or an alkyl group which may have a substituent, and more preferably a hydrogen atom.

R^{C10} is preferably a hydrogen atom, an alkyl group which may have a substituent, or an amino group which may have a substituent, more preferably a hydrogen atom or an amino group which may have a substituent, and still more preferably an amino group which may have a substituent.

R^{C11} is preferably a hydrogen atom or an alkyl group which may have a substituent, and more preferably a hydrogen atom.

In Formula (C4), R^{C12} to R^{C14} each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent.

Examples of an aspect of each group represented by R^{C12} to R^{C14} include the above-described groups represented by R^{C1} to R^{C3} in Formula (C1).

R^{C12} is preferably a hydrogen atom or an alkyl group which may have a substituent, and more preferably an alkyl group which may have a substituent.

Another suitable aspect of R^{C12} is preferably an alkyl group which may have a substituent, an amino group which may have a substituent, a thiol group, a hydroxy group, a halogen atom, a sugar group which may have a substituent, or a polyoxyalkylene group-containing group which may have a substituent.

R^{C13} is preferably a hydrogen atom or an alkyl group which may have a substituent, and more preferably an alkyl group which may have a substituent.

R^{C14} is preferably a hydrogen atom or an alkyl group which may have a substituent.

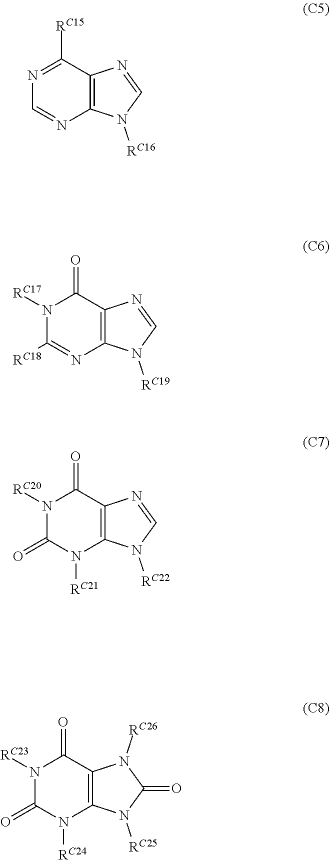

In Formula (C5), R^{C15} and R^{C16} each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent.

Examples of an aspect of each group represented by R^{C15} and R^{C16} include the above-described groups represented by R^{C1} to R^{C3} in Formula (C1).

R^{C15} is preferably a hydrogen atom, an alkyl group which may have a substituent, or an amino group which may have a substituent, and more preferably an amino group which may have a substituent.

R^{C16} is preferably a hydrogen atom, an alkyl group which may have a substituent, or a sugar group which may have a substituent, more preferably a hydrogen atom or a sugar group which may have a substituent, and still more preferably a hydrogen atom.

In Formula (C6), R^{C17} to R^{C19} each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent.

Examples of an aspect of each group represented by R^{C17} to R^{C19} include the above-described groups represented by R^{C1} to R^{C3} in Formula (C1).

R^{C17} to R^{C19} are preferably a hydrogen atom or an alkyl group which may have a substituent, and more preferably a hydrogen atom.

In Formula (C7), R^{C20} to R^{C22} each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent.

Examples of an aspect of each group represented by R^{C20} to R^{C22} include the above-described groups represented by R^{C1} to R^{C3} in Formula (C1).

R^{C20} to R^{C22} are preferably a hydrogen atom or an alkyl group which may have a substituent, and more preferably a hydrogen atom.

In Formula (C8), R^{C23} to R^{C26} each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent.

Examples of an aspect of each group represented by R^{C23} to R^{C26} include the above-described groups represented by R^{C1} to R^{C3} in Formula (C1).

R^{C23} to R^{C26} are preferably a hydrogen atom or an alkyl group which may have a substituent, and more preferably a hydrogen atom.

Examples of the purine compound include purine, adenine, guanine, hypoxanthine, xanthine, theobromine, caffeine, uric acid, isoguanine, adenosine, kinetin, enprofylline, theophylline, xanthosine, 7-methylxanthosine, 7-methylxanthine, eritadenine, dimethyladenine, 3-methylxanthine, 1,7-dimethylxanthine, 1-methylxanthine, 1,3-dipropyl-7-methylxanthine, 3,7-dihydro-7-methyl-1H-purine-2,6-dione, 1,7-dipropyl-3-methylxanthine, 1-methyl-3,7-dipropylxanthine, 1,3-dipropyl-7-methyl-8-dicyclopropylmethylxanthine, 1,3-dibutyl-7-(2-oxopropyl) xanthine, 1-butyl-3,7-dimethylxanthine, 3,7-dimethyl-1-propylxanthine, mercaptopurine, 2-aminopurine, 6-benzylaminopurine (6-benzyladenine), nelarabine, vidarabine, 2,6-dichloropurine, aciclovir, N6-benzoyladenosine, trans-zeatin, entecavir, valaciclovir, abacavir, 2′-deoxyguanosine, disodium inosinate, ganciclovir, guanosine 5′-disodium monophosphate, O-cyclohexylmethylguanine, N2-isobutyryl-2′-deoxyguanosine, β-nicotinamide adenine dinucleotide phosphate, 6-chloro-9-(tetrahydropyran-2-yl) purine, clofarabine, 7-(2,3-dihydroxypropyl) theophylline, 6-mercaptopurine, proxyphylline, 2,6-diaminopurine, 2′,3′-dideoxyinosine, theophylline-7-acetic acid, 2-chloroadenine, 2-amino-6-chloropurine, 8-bromo-3-methylxanthine, 2-fluoroadenine, penciclovir, 9-(2-hydroxyethyl) adenine, 7-(2-chloroethyl) theophylline, 2-amino-6-iodopurine, 2-thioxanthine, 2-amino-6-methoxypurine, N-acetylguanine, adefovir dipivoxil, 8-chlorotheophylline, and 6-methoxypurine.

Among these, the purine compound preferably includes at least one selected from the group consisting of purine, adenine, hypoxanthine, xanthine, theobromine, caffeine, uric acid, adenosine, 6-benzyladenine, kinetin, dimethyladenine, methyladenine, enprofylline, xanthosine, 7-methylxanthosine, 7-methylxanthine, theophylline, eritadenine, paraxanthine, 3-methylxanthine, 1,7-dimethylxanthine, and 1-methylxanthine; more preferably includes at least one selected from the group consisting of adenine, hypoxanthine, xanthine, adenosine, 6-benzyladenine, kinetin, dimethyladenine, and methyladenine; and still more preferably includes at least one selected from the group consisting of adenine, xanthine, adenosine, 6-benzyladenine, kinetin, dimethyladenine, and methyladenine.

The purine compound may be used alone or in combination of two or more thereof.

From the viewpoint that the effect of the present invention is more excellent, a content of the purine compound is preferably 0.0000005% to 0.5% by mass, more preferably 0.000001% to 0.3% by mass, still more preferably 0.00001% to 0.2% by mass, and particularly preferably 0.00001% to 0.05% by mass with respect to the total mass of the treatment liquid.

From the viewpoint that the effect of the present invention is more excellent, the content of the purine compound is preferably 0.01% to 10.0% by mass, more preferably 0.02% to 8.0% by mass, and still more preferably 0.05% to 5.0% by mass with respect to the total mass of components in the treatment liquid excluding a solvent.

### [Amine Compound]

The treatment liquid contains an amine compound. The amine compound is a compound in which at least one hydrogen atom of ammonia is replaced with another substituent.

The amine compound is a compound different from the above-described purine compound, and the purine compound is not included in the amine compound.

The amine compound includes at least two of one amine compound A described later, and one or two or more amine compounds B different from the amine compound A.

The amine compound A corresponds to one compound, and the amine compound B corresponds to one or two or more compounds other than the amine compound A, which are contained in the treatment liquid. For example, in a case where the treatment liquid contains one kind of tertiary amine compound and two kinds of secondary amine compounds, the one kind of tertiary amine compound corresponds to the amine compound A, and the two kinds of secondary amine compounds correspond to the amine compound B, respectively.

In a case where the treatment liquid contains two or more kinds of tertiary amine compounds, a tertiary amine compound having the highest content is the amine compound A. In a case where contents of the two or more kinds of tertiary amine compounds are the same, any one tertiary amine compound is defined as the amine compound A.

From the viewpoint of suitability for use in the present invention, a flash point of the amine compound is preferably −10° C. to 240° C., more preferably 10° C. to 220° C., and still more preferably 30° C. to 220° C.

From the viewpoint that the effect of the present invention is more excellent, it is preferable that the amine compound does not have a cyclic structure.

From the viewpoint that the effect of the present invention is more excellent, a solubility parameter (SP) value of the amine compound is preferably 11 to 33 MPa^{1/2}, more preferably 13 to 29 MPa^{1/2}, and still more preferably 15 to 25 MPa^{1/2}.

The SP value is a Hansen solubility parameter according to the expression described in Hansen Solubility Parameters: A User's Handbook, Second Edition, C. M. Hansen (2007), Taylor and Francis Group, LLC (HSPiP Manual), and refers to a value calculated by the following expression(S) using “Practical Hansen Solubility Parameters HSPiP 5th Edition” (software version 5.1.03).

$${( SP value )}^{2} = {δ}_{d}^{2} + {δ}_{p}^{2} + {δ}_{h}^{2} \qquad Equation ( S )$$

In Equation(S), da represents energy due to a dispersion force, &p represents energy due to a dipole-dipole interaction, and & represents energy due to a hydrogen bond. Three or more kinds of amine compounds may be used in combination.

From the viewpoint that the effect of the present invention is more excellent, a content of the amine compound is preferably 0.001% to 50.0% by mass, more preferably 0.01% to 30.0% by mass, still more preferably 0.03% to 10.0% by mass, and particularly preferably 0.03% to 3.0% by mass with respect to the total mass of the treatment liquid.

From the viewpoint that the effect of the present invention is more excellent, the content of the amine compound is preferably 50.0% to 99.99% by mass, more preferably 70.0% to 99.99% by mass, still more preferably 80.0% to 99.99% by mass, and particularly preferably 90% to 99.99% by mass with respect to the total mass of components in the treatment liquid excluding a solvent.

A mass ratio of the above-described content of the purine compound to the content of the amine compound (content of purine compound/content of amine compound) is 0.0001 to 0.1, and from the viewpoint that the effect of the present invention is more excellent, it is more preferably 0.0002 to 0.05.

In a case where the mass ratio of the content of the purine compound to the content of the amine compound is less than 0.0001, the metal component is likely to be corroded; and in a case where the mass ratio is more than 0.1, the amount of residues increases, which are not preferable. That is, in a case where the mass ratio of the content of the purine compound to the content of the amine compound is out of the range of 0.0001 to 0.1, both the cleanability and the anticorrosion properties cannot be achieved, which is not preferable.

The “content of the amine compound” means the total content of all amine compounds contained in the treatment liquid.

### <Amine Compound A>

The amine compound includes the amine compound A.

The amine compound A is a tertiary amine compound having at least one tertiary amino group (>N—) in a molecule.

The nitrogen atom included in the tertiary amino group of the amine compound A may be a ring member atom.

The amine compound A may have other substituents in addition to the tertiary amino group. Examples of the substituent include a hydroxy group.

The amine compound A may have two or more tertiary amino groups. That is, the amine compound A may be a diamine compound or a polyamine compound.

From the viewpoint that the effect of the present invention is more excellent, it is preferable that the amine compound A does not have a cyclic structure.

From the viewpoint that the effect of the present invention is more excellent, a molecular weight of the amine compound A is preferably 60 to 300, more preferably 80 to 170, still more preferably 100 to 160, and particularly preferably 105 to 150.

From the viewpoint that the effect of the present invention is more excellent, the number of carbon atoms in the amine compound A is preferably 3 to 20, more preferably 4 to 11, still more preferably 6 to 9, and particularly preferably 6 to 8.

From the viewpoint that the effect of the present invention is more excellent, a pKa of the amine compound A is preferably 8.0 to 20.0, more preferably 10.0 to 18.0, and still more preferably 11.0 to 16.0.

The pKa is an acid dissociation constant calculated using “ChemDraw” (registered trademark, manufactured by CambridgeSoft Corporation, software version: 20.1.1.125).

In a case where the compound has two or more pKa's, it is sufficient that a pKa having the largest value is included in the above-described suitable range.

From the viewpoint that the effect of the present invention is more excellent, it is preferable that the amine compound A satisfies a plurality of the above-described suitable conditions.

The amine compound A is preferably one selected from the group consisting of a compound represented by Formula (A1) and a compound represented by Formula (A2); and more preferably a compound represented by Formula (A1).

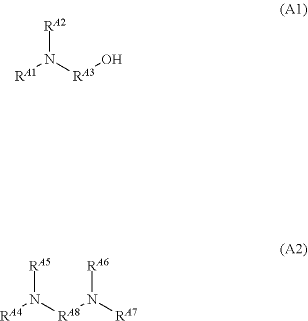

In Formula (A1), R^{A1} and R^{A2} each independently represent an alkyl group which may have a substituent,
R^{A3} represents an alkylene group which may have a substituent, and
two of R^{A1} to R^{A3} may be bonded to each other through a single bond or a divalent linking group to form a ring.

R^{A1} and R^{A2} each independently represent an alkyl group which may have a substituent.

The above-described alkyl group may be linear, branched, or cyclic.

The number of carbon atoms in the above-described alkyl group is preferably 1 to 30, more preferably 1 to 15, still more preferably 1 to 5, and particularly preferably 1 to 3.

Examples of the substituent contained in the above-described alkyl group include a halogen atom such as a fluorine atom, a chlorine atom, and a bromine atom; an alkoxy group; a hydroxy group; an acyl group such as an acetyl group, a propionyl group, and a benzoyl group; a cyano group; and a nitro group, and a hydroxy group is preferable.

In a case where the above-described alkyl group has a hydroxy group, the number of hydroxy groups contained in the alkyl group is preferably 1 to 5, more preferably 1 to 3, and still more preferably 1.

Among these, as R^{A1} and R^{A2}, an alkyl group having 1 to 10 carbon atoms is preferable; an alkyl group having 1 to 5 carbon atoms is more preferable; a methyl group, an ethyl group, a propyl group, an isopropyl group, a butyl group, an isobutyl group, or a 2-hydroxyethyl group is still more preferable; and a methyl group, an ethyl group, or an isopropyl group is particularly preferable.

R^{A3} represents an alkylene group which may have a substituent.

The above-described alkylene group may be linear, branched, or cyclic.

The number of carbon atoms in the above-described alkylene group is preferably 1 to 10, more preferably 1 to 6, and still more preferably 1 to 4.

Examples of the substituent contained in the above-described alkylene group include the substituents which can be adopted by R^{A1} and R^{A2}.

Among these, as R^{A3}, an alkylene group having 1 to 6 carbon atoms is preferable; an alkylene group having 1 to 4 carbon atoms is more preferable; a methylene group, an ethylene group, a propylene group, a methylethylene group, an ethylethylene group, a 1-methylpropylene group, a 1,1-dimethylethylene group, or a 1,2-dimethylethylene group is still more preferable; and an ethylene group, a methylethylene group, or a 1,1-dimethylethylene group is particularly preferable.

Two of R^{A1} to R^{A3} may be bonded to each other through a single bond or a divalent linking group to form a ring. The above-described ring to be formed may be monocyclic or polycyclic.

Examples of the above-described divalent linking group include a divalent hydrocarbon group (for example, a divalent aliphatic hydrocarbon group such as an alkylene group (preferably having 1 to 10 carbon atoms and more preferably having 1 to 5 carbon atoms), an alkenylene group (preferably having 2 to 10 carbon atoms and more preferably having 2 to 5 carbon atoms), and an alkynylene group (preferably having 2 to 10 carbon atoms and more preferably having 2 to 5 carbon atoms), and a divalent aromatic hydrocarbon ring group such as an arylene group), a divalent heterocyclic group, —O—, —S—, —SO₂—, —NH—, —N(Q)-, —CO—, and a group obtained by combining these groups (for example, —O-divalent hydrocarbon group-, —(O-divalent hydrocarbon group)ₘ-O-(m represents an integer of 1 or more), -divalent hydrocarbon group-O—CO—, and the like). Q represents a hydrogen atom or an alkyl group.

In a case where two of R^{A1} to R^{A3} are bonded to each other through a single bond or a divalent linking group to form a ring, the number of atoms forming the ring is preferably 3 to 20, more preferably 3 to 10, and still more preferably 5 or 6.

For example, in a case where R^{A1} and R^{A2} are bonded to each other through a single bond or a divalent linking group, a bonding position formed by removing one hydrogen atom from the alkyl group in R^{A1} and a bonding position formed by removing one hydrogen atom from the alkyl group in R^{A2} are bonded to each other through a single bond or a divalent linking group.

More specifically, the compound represented by Formula (A1) may be a compound represented by Formula (A1-1). The compound represented by Formula (A1-1) corresponds to a compound obtained by bonding R^{A1} and R^{A2} to each other through a single bond or a divalent linking group to form a ring.

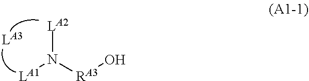

In Formula (A1-1), L^{A1} and L^{A2} each independently represent an alkylene group which may have a substituent.

The above-described alkylene group may be linear, branched, or cyclic.

The number of carbon atoms in the above-described alkylene group is preferably 1 to 10, more preferably 1 to 6, and still more preferably 1 to 4.

Examples of the substituent contained in the above-described alkylene group include the substituents which can be adopted by R^{A1} and R^{A2}.

Among these, as L^{A1} and L^{A2}, an alkylene group having 1 to 6 carbon atoms is preferable, and an alkylene group having 1 to 4 carbon atoms is more preferable.

In Formula (A1-1), L^{A3} represents a single bond or a divalent linking group. Examples of the divalent linking group represented by L^{A3} include the groups exemplified as the above-described divalent linking group in a case where two of R^{A1} to R^{A3} are bonded to each other through a single bond or a divalent linking group to form a ring.

L^{A3} is preferably a single bond.

The definition and suitable range of R^{A3} in Formula (A1-1) are the same as the definition and suitable range of R^{A3} in Formula (A1).

In addition, for example, in a case where R^{A1} and R^{A3} are bonded to each other through a divalent linking group, a bonding position formed by removing one hydrogen atom from the alkyl group in R^{A1} and a bonding position formed by removing one hydrogen atom from the alkylene group in R^{A3} are bonded to each other through a single bond or a divalent linking group.

More specifically, the compound represented by Formula (A1) may be a compound represented by Formula (A1-2). The compound represented by Formula (A1-2) corresponds to a compound obtained by bonding R^{A1} and R^{A3} to each other through a single bond or a divalent linking group to form a ring.

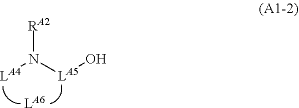

In Formula (A1-2), L^{A4} represents an alkylene group which may have a substituent.

The above-described alkylene group may be linear, branched, or cyclic.

The number of carbon atoms in the above-described alkylene group is preferably 1 to 10, more preferably 1 to 6, and still more preferably 1 to 4.

Examples of the substituent contained in the above-described alkylene group include the substituents which can be adopted by R^{A1} and R^{A2}.

Among these, as L^{A4}, an alkylene group having 1 to 6 carbon atoms is preferable, and an alkylene group having 1 to 4 carbon atoms is more preferable.

In Formula (A1-2), L^{A5} represents a trivalent saturated aliphatic hydrocarbon group which may have a substituent.

The above-described saturated aliphatic hydrocarbon group may be linear, branched, or cyclic.

The number of carbon atoms in the above-described saturated aliphatic hydrocarbon group is preferably 1 to 10, more preferably 1 to 6, and still more preferably 1 to 4.

Examples of the substituent contained in the above-described saturated aliphatic hydrocarbon group include the substituents which can be adopted by R^{A1} and R^{A2}.

Among these, as L^{A5}, a trivalent saturated aliphatic hydrocarbon group having 1 to 6 carbon atoms is preferable, and a trivalent saturated aliphatic hydrocarbon group having 1 to 4 carbon atoms is more preferable.

In Formula (A1-2), L^{A6} represents a single bond or a divalent linking group. Examples of the divalent linking group represented by L^{A6} include the groups exemplified as the above-described divalent linking group in a case where two of R^{A1} to R^{A3} are bonded to each other through a single bond or a divalent linking group to form a ring.

L^{A6} is preferably a single bond.

The definition and suitable range of R^{A2} in Formula (A1-2) are the same as the definition and suitable range of R^{A2} in Formula (A1).

As the compound represented by Formula (A1-2), a compound represented by Formula (A1-3) is preferable.

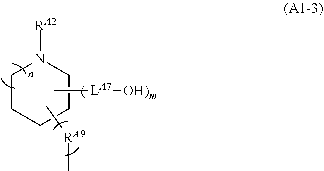

In Formula (A1-3), L^{A7} represents a single bond or an alkylene group.

The above-described alkylene group is preferably linear or branched.

The number of carbon atoms in the above-described alkylene group is preferably 1 to 6 and more preferably 1 or 2.

In Formula (A1-3), R^{A9} represents an alkyl group.

The above-described alkyl group is preferably linear or branched.

The number of carbon atoms in the above-described alkyl group is preferably 1 to 5 and more preferably 1 to 3.

n represents 0 or 1. In a case where n is 0, the compound represented by Formula (A1-3) has a 5-membered ring structure; and in a case where n is 1, the compound represented by Formula (A1-3) has a 6-membered ring structure.

m represents an integer of 1 or 2. m is preferably 1.

1 represents an integer of 0 to 4.

Examples of the compound represented by Formula (A1) include 2-(diisopropylamino) ethanol, 2-(diethylamino) ethanol (DEAE), 2-(dimethylamino) ethanol (DMAE), 2-(dimethylamino)-2-methyl-1-propanol (DMAMP), N-tert-butyldiethanolamine (t-BDEA), 1-methyl-2-piperidinemethanol, 4-hydroxy-1,2,2,6,6-pentamethylpiperidine (HOPEMP), 1-piperidineethanol, 1-methyl-3-piperidinemethanol, 1-methyl-3-pyrrolidinol, 3-hydroxy-1-methylpiperidine, N-methyldiethanolamine (MDEA), N-ethyldiethanolamine (EDEA), triethanolamine, 1-[bis(2-hydroxyethyl)amino]-2-propanol, and 2-(dibutylamino) ethanol.

In Formula (A2), R^{A4} to R^{A7} each independently represent an alkyl group which may have a substituent.

Two of R^{A4} to R^{A7} may be bonded to each other through a single bond or a divalent linking group to form a ring. In addition, as an example in which two of R^{A4} to R^{A7} described above form a ring, both R^{A4} and R^{A7}, and R^{A5} and R^{A6} may be bonded to each other through a single bond or a divalent linking group to form a ring.

R^{A8} represents an alkylene group which may have a hydroxy group or may have a linking group represented by —NR^{Ax}—. R^{Ax} represents a hydrogen atom or an alkyl group. R^{A4} to R^{A7} each independently represent an alkyl group which may have a substituent.

The number of carbon atoms in the above-described alkyl group is preferably 1 to 30, more preferably 1 to 15, and still more preferably 1 to 6.

Examples of the substituent contained in the above-described alkyl group include the substituents which can be adopted by R^{A1} and R^{A2}.

Among these, as R^{A4} to R^{A7}, an alkyl group having 1 to 3 carbon atoms is preferable, a methyl group, an ethyl group, a propyl group, or an isopropyl group is more preferable, and a methyl group is still more preferable.

R^{A8} represents an alkylene group which may have a hydroxy group or may have a linking group represented by —NR^{Ax}—. R^{Ax} represents a hydrogen atom or an alkyl group.

The number of carbon atoms in the above-described alkylene group is preferably 1 to 10, more preferably 1 to 8, and still more preferably 1 to 6.

In a case where the above-described alkylene group has a hydroxy group, the number of hydroxy groups contained in the alkylene group is preferably 1 to 5, more preferably 1 to 3, and still more preferably 1.

The number of linking groups represented by —NR^{Ax}-contained in the above-described alkylene group is preferably 0 to 3, more preferably 0 or 1, and still more preferably 0.

R^{Ax} represents a hydrogen atom or an alkyl group, preferably a hydrogen atom or an alkyl group having 1 to 3 carbon atoms, more preferably a hydrogen atom, a methyl group, an ethyl group, or an isopropyl group, and still more preferably a methyl group.

Two of R^{A4} to R^{A7} may be bonded to each other through a single bond or a divalent linking group to form a ring. The above-described ring to be formed may be monocyclic or polycyclic.

Examples of the above-described divalent linking group include the groups exemplified as the above-described divalent linking group in a case where two of R^{A1} to R^{A3} are bonded to each other through a single bond or a divalent linking group to form a ring.

Examples of the compound represented by Formula (A2) include tetramethyl-1,3-diaminobutane, tetramethyl-1,6-diaminohexane, tetramethyl-1,3-diaminopropane, pentamethyldipropylene triamine, 1,4-bis(2-hydroxyethyl) piperazine (BHEP), 1,4-bis(2-aminoethyl) piperazine (BAEP), 1,4-bis(3-aminopropyl) piperazine (BAPP), and 1,4-diazabicyclo[2.2.2]octane (DABCO).

Among these, as the amine compound A, 2-(diisopropylamino) ethanol, DEAE, DMEA, DMAMP, 1-methyl-2-piperidinemethanol, 4-hydroxy-1,2,2,6,6-pentamethylpiperidine, 1-piperidineethanol, 1-methyl-3-piperidinemethanol, 1-methyl-3-pyrrolidinol, t-BDEA, 3-hydroxy-1-methylpiperidine, tetramethyl-1,6-diaminohexane, tetramethyl-1,3-diaminopropane, pentamethyl dipropylene triamine, or DABCO is preferable; 2-(diisopropylamino) ethanol, DEAE, DMEA, DMAMP, 1-methyl-2-piperidinemethanol, 4-hydroxy-1,2,2,6,6-pentamethylpiperidine, 1-piperidineethanol, 1-methyl-3-piperidinemethanol, 1-methyl-3-pyrrolidinol, or t-BDEA is more preferable; 2-(diisopropylamino) ethanol, DEAE, DMAMP, 1-methyl-2-piperidinemethanol, 4-hydroxy-1,2,2,6,6-pentamethylpiperidine (HOPEMP), or 1-piperidineethanol is still more preferable; and 2-(diisopropylamino) ethanol, DEAE, or DMAMP is particularly preferable.

From the viewpoint that the effect of the present invention is more excellent, a content of the amine compound A is preferably 0.0001% to 20.0% by mass, more preferably 0.0005% to 10.0% by mass, still more preferably 0.001% to 5.0% by mass, and particularly preferably 0.001% to 0.5% by mass with respect to the total mass of the treatment liquid.

From the viewpoint that the effect of the present invention is more excellent, the content of the amine compound A is preferably 10.0% to 99.5% by mass, more preferably 15.0% to 90.0% by mass, still more preferably 30.0% to 85.0% by mass, and particularly preferably 50.0% to 85.0% by mass with respect to the total mass of components in the treatment liquid excluding a solvent.

As described above, in a case where the amine compound includes two or more kinds of tertiary amine compounds, a tertiary amine compound having the highest content is the amine compound A. For example, in a case where the amine compound includes two kinds of tertiary amine compounds, a tertiary amine compound having the highest content is the amine compound A, and the remaining tertiary amine compound is the amine compound B.

### <Amine Compound B>

The amine compound includes one or two or more amine compounds B different from the amine compound A.

The amine compound B is a compound of a different type from the amine compound A, and examples thereof include a compound having at least one or more groups selected from the group consisting of a primary amino group (—NH₂), a secondary amino group (>NH), and a tertiary amino group (>N—) (hereinafter, also referred to as a primary to tertiary amino group). That is, examples of the amine compound B include a primary amine compound, a secondary amine compound, and a tertiary amine compound. Furthermore, in a case where the compound has amino groups of different classes, it is classified into the highest amine compound.

The amine compound B may have other substituents in addition to the primary to tertiary amino group. Examples of the substituent include a hydroxy group.

It is preferable that the amine compound B has one primary to tertiary amino group and further has a group selected from the group consisting of a primary to tertiary amino group and a hydroxy group.

From the viewpoint of more excellent cleanability, at least one of the one or two or more amine compounds B is preferably an amine compound having two or more nitrogen atoms, and more preferably an amine compound having three or more nitrogen atoms.

From the viewpoint that the effect of the present invention is more excellent, it is also preferable that at least one of the one or two or more amine compounds B is a tertiary amine compound. In a case where at least one of the one or two or more amine compounds B is a tertiary amine compound, the tertiary amine compound may be the compound represented by Formula (A2) described above.

Examples of the tertiary amine compound include piperazine compounds such as 1-methylpiperazine, 1-ethylpiperazine, 1-propylpiperazine, and 1-butylpiperazine; polyamine compounds such as 2-(dimethylamino)ethylamine, 2-(diethylamino)ethylamine, and N,N,N′,N″,N″-pentamethyldiethylenetriamine (PMDETA); and the compounds exemplified as the amine compound A.

Examples of other amine compounds include a primary amine compound and a secondary amine compound. Specific examples thereof include a monoamine compound having only one group selected from the group consisting of a primary amino group and a secondary amino group, and a polyamine compound having two or more groups selected from the group consisting of a primary amino group and a secondary amino group.

As the monoamine compound, a monoamine compound having a hydroxy group is preferable; and examples thereof include diisopropanolamine, dimethanolamine, diethanolamine, 2-(ethylamino) ethanol, 2-(propylamino) ethanol, N-methylethanolamine (N-MEA), 2-amino-2-methyl-1-propanol (AMP), 2-methyl-2-(methylamino) propan-1-ol (MAMP), N-phenyldiethanolamine (Ph-DEA), N-butanolamine, and N-cyclohexylethanolamine.

Examples of the polyamine compound include ethylenediamine (EDA), 1,3-propanediamine (PDA), 1,2-propanediamine, 1,3-butanediamine, 1,4-butanediamine, isophoronediamine, 2-(dimethylamino)ethylamine, 1,2-bis(methylamino) ethane, 3-diethylaminopropylamine, 1,2-diaminocyclohexane, 1,4-diamino-3,6-diethylcyclohexane, diethylenetriamine (DETA), triethylenetetramine (TETA), bis[3-(dimethylamino) propyl]amine, and bis(aminopropyl)ethylenediamine (BAPEDA).

As the amine compound B, a compound represented by Formula (A3) is also preferable.

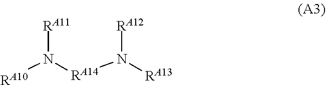

In Formula (A3), R^{A10} to R^{A13} each independently represent a hydrogen atom or an alkyl group which may have a substituent.

Two of R^{A10} to R^{A13} may be bonded to each other through a single bond or a divalent linking group to form a ring. In addition, as an example in which two of R^{A10} to R^{A13} described above form a ring, both R^{A10} and R^{A13}, and R^{A11} and R^{A12} may be bonded to each other through a single bond or a divalent linking group to form a ring.

R^{A14} represents an alkylene group which may have a hydroxy group or may have a linking group represented by —NR^{Ax}—. R^{Ax} represents a hydrogen atom or an alkyl group.

R^{A10} to R^{A13} each independently represent a hydrogen atom or an alkyl group which may have a substituent.

The number of carbon atoms in the above-described alkyl group is preferably 1 to 30, more preferably 1 to 15, and still more preferably 1 to 6.

Examples of the substituent contained in the above-described alkyl group include the substituents which can be adopted by R^{A1} and R^{A2}.

Among these, as R^{A10} to R^{A13}, a hydrogen atom or an alkyl group having 1 to 3 carbon atoms is preferable, a hydrogen atom, a methyl group, an ethyl group, a propyl group, or an isopropyl group is more preferable, and a methyl group is still more preferable.

The definition and suitable range of R^{A14} are the same as the definition and suitable range of R^{A8} in Formula (A2).

Two of R^{A10} to R^{A13} may be bonded to each other through a single bond or a divalent linking group to form a ring. The above-described ring to be formed may be monocyclic or polycyclic.

Examples of the above-described divalent linking group include the groups exemplified as the above-described divalent linking group in a case where two of R^{A1} to R^{A3} are bonded to each other through a single bond or a divalent linking group to form a ring.

Among these, the amine compound B preferably includes at least one selected from the group consisting of 2-(dimethylamino)ethylamine, 1,2-bis(methylamino) ethane, PMDETA, AMP, and diisopropanolamine; more preferably includes at least one selected from the group consisting of 2-(dimethylamino)ethylamine, 1,2-bis(methylamino) ethane, and PMDETA; and still more preferably includes PMDETA.

The amine compound B may be used alone or in combination of two or more thereof.

From the viewpoint that the effect of the present invention is more excellent, the total content of the amine compound B is preferably 0.0001% to 20.0% by mass, more preferably 0.0005% to 10.0% by mass, still more preferably 0.001% to 5.0% by mass, and particularly preferably 0.001% to 0.1% by mass with respect to the total mass of the treatment liquid.

From the viewpoint that the effect of the present invention is more excellent, the total content of the amine compound B is preferably 5.0% to 99.5% by mass, more preferably 10.0% to 85.0% by mass, still more preferably 10.0% to 70.0% by mass, and particularly preferably 15.0% to 50.0% by mass with respect to the total mass of components in the treatment liquid excluding a solvent.

In a case where one amine compound B is used, the total content of the amine compound B means the content of the compound itself; and in a case where two or more amine compounds B are used, the total content of the amine compound B means the total content of these compounds.

The treatment liquid may contain other components in addition to the above-described components (the purine compound and the amine compound).

Hereinafter, other components will be described in detail.

### [Water]

The treatment liquid may contain water as a solvent.

The type of water used in the treatment liquid may be any type of water as long as it does not adversely affect the semiconductor substrate; and distilled water, deionized (DI) water, or pure water (ultrapure water) can be used. The pure water (ultrapure water) is preferable from the viewpoint that it contains almost no impurities and has less influence on a semiconductor substrate in a step of manufacturing the semiconductor substrate.

A content of water may be a remainder of components which can be contained in the treatment liquid.

The content of the water is preferably 1.0% by mass or more, more preferably 30.0% by mass or more, still more preferably 60.0% by mass or more, and particularly preferably 80.0% by mass or more with respect to the total mass of the treatment liquid. The upper limit thereof is preferably 99.999% by mass or less, more preferably 99.99% by mass or less, still more preferably 99.95% by mass or less, even more preferably 99.9% by mass or less, even still more preferably 99.0% by mass or less, and particularly preferably 97.0% by mass or less with respect to the total mass of the treatment liquid.

### [Other Components]

The treatment liquid may contain, in addition to the above-described compounds, at least one component selected from the group consisting of a surfactant, a pH adjuster, an organic solvent, an organic acid, a polymer, a polyhydroxy compound having a molecular weight of 500 or more, and an oxidant.

Hereinafter, other components will be described.

### <Surfactant>

The surfactant is not particularly limited as long as it is a compound having a hydrophilic group and a hydrophobic group (lipophilic group) in one molecule; and examples thereof include a nonionic surfactant and an anionic surfactant.

In many cases, the surfactant has at least one hydrophobic group selected from the group consisting of an aliphatic hydrocarbon group, an aromatic hydrocarbon group, and a group obtained by combining these groups.

The number of carbon atoms in the surfactant is preferably 16 to 100.

Examples of the nonionic surfactant include an ester-type nonionic surfactant, an ether-type nonionic surfactant, and an ester-ether-type nonionic surfactant; and an ether-type nonionic surfactant is preferable.

As the nonionic surfactant, for example, compounds exemplified in paragraph of WO2022/044893A can also be used, the contents of which are incorporated herein by reference.

Examples of the anionic surfactant include a phosphoric acid ester-based surfactant having a phosphoric acid ester group, a phosphonic acid-based surfactant having a phosphonate group, a sulfonic acid-based surfactant having a sulfo group, a carboxylic acid-based surfactant having a carboxy group, and a sulfuric acid ester-based surfactant having a sulfuric acid ester group.

As the anionic surfactant, for example, compounds exemplified in paragraphs to of WO2022/044893A can also be used, the contents of which are incorporated herein by reference.

The surfactant may be used alone, or two or more types thereof may be used in combination.

From the viewpoint of excellent performance of the treatment liquid, a content of the surfactant is preferably 0.0001% to 5.00% by mass, more preferably 0.0005% to 1.00% by mass, and still more preferably 0.001% to 0.10% by mass with respect to the total mass of the treatment liquid.

From the viewpoint of excellent performance of the treatment liquid, the content of the surfactant is preferably 0.1% to 50.0% by mass, more preferably 0.5% to 30.0% by mass, and still more preferably 1.0% to 10.0% by mass with respect to the total mass of components in the treatment liquid excluding a solvent.

### <pH Adjuster>

The treatment liquid may include a pH adjuster to adjust and maintain the pH of the treatment liquid.

The pH adjuster is a basic compound and an acidic compound, which are different from the above-described compounds (the purine compound, the amine compound, and the like) which can be contained in the treatment liquid. However, it is permissible to adjust the pH of the treatment liquid by adjusting the adding amount of each of the above-described components.

The basic compound is a compound which exhibits basicity (a pH of more than 7.0) in an aqueous solution.

Examples of the basic compound include a basic inorganic compound.

Examples of the basic inorganic compound include alkali metal hydroxides such as sodium hydroxide and potassium hydroxide, and alkaline earth metal hydroxides.

The acidic compound is a compound which exhibits acidity (a pH of less than 7.0) in an aqueous solution.

Examples of the acidic compound include an inorganic acid.

Examples of the inorganic acid include hydrochloric acid, sulfuric acid, sulfurous acid, nitric acid, nitrite, phosphoric acid, boric acid, and hexafluorophosphoric acid.

As the acidic compound, a salt of the acidic compound may be used as long as it is an acid or an acid ion (anion) in an aqueous solution.

The pH adjuster may be used alone, or two or more types thereof may be used in combination.

A content of the pH adjuster can be selected depending on the type and amount of components other than the pH adjuster and the target pH of the treatment liquid. For example, the content of the pH adjuster is preferably 0.0001% to 10% by mass, and more preferably 0.001% to 8% by mass with respect to the total mass of the treatment liquid.

The content of the pH adjuster is preferably 0.01% to 80% by mass and more preferably 0.1% to 60% by mass with respect to the total mass of components in the treatment liquid excluding a solvent.

### <Organic Solvent>

Examples of the organic solvent include known organic solvents, for example, an alcohol-based solvent, a glycol-based solvent, a glycol ether-based solvent, and a ketone-based solvent.

It is preferable that the organic solvent is mixed with water at an optional ratio.

Examples of the alcohol-based solvent include methanol, ethanol, propanol, isopropyl alcohol, 1-butanol, 2-butanol, isobutyl alcohol, and tert-butyl alcohol.

Examples of the glycol-based solvent include ethylene glycol, propylene glycol, diethylene glycol, dipropylene glycol, triethylene glycol, and tetraethylene glycol.

Examples of the glycol ether-based solvent include glycol monoether.

Examples of the glycol monoether include ethylene glycol monomethyl ether, ethylene glycol monoethyl ether, ethylene glycol mono-n-propyl ether, ethylene glycol monoisopropyl ether, ethylene glycol mono-n-butyl ether, diethylene glycol monomethyl ether, diethylene glycol monoethyl ether, diethylene glycol monobutyl ether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether, ethylene glycol monobenzyl ether, and diethylene glycol monobenzyl ether.

Examples of the ketone-based solvent include acetone, methyl ethyl ketone, methyl isobutyl ketone, and cyclohexanone.

The organic solvent may be used alone, or two or more types thereof may be used in combination.

A content of the organic solvent is preferably 0.001% to 5.00% by mass, more preferably 0.005% to 3.00% by mass, and still more preferably 0.01% to 1.00% by mass with respect to the total mass of the treatment liquid.

### <Organic Acid>

Examples of the organic acid include carboxylic acids such as an aliphatic carboxylic acid and an aromatic carboxylic acid, and a phosphonic acid.

The organic acid may be in a form of a salt. Examples of the above-described salt include an inorganic salt.

Examples of the aliphatic carboxylic acid include succinic acid, tartaric acid, maleic acid, oxalic acid, malonic acid, glutaric acid, adipic acid, pimelic acid, sebacic acid, formic acid, citric acid, malic acid, glycolic acid, gluconic acid, heptonic acid, and lactic acid.

Examples of the aromatic carboxylic acid include phenyl lactic acid, hydroxyphenyl lactic acid, phenyl succinic acid, phthalic acid, isophthalic acid, terephthalic acid, gallic acid, trimellitic acid, mellitic acid, and cinnamic acid.

As the phosphonic acid, compounds described in paragraphs to of WO2018/020878A and compounds ((co) polymers) described in paragraphs to of WO2018/030006A can be used, the contents of which are incorporated herein by reference.

The organic acid may be used alone, or two or more types thereof may be used in combination.

A content of the organic acid is preferably 0.0001% to 5.00% by mass, more preferably 0.0005% to 1.00% by mass, and still more preferably 0.001% to 0.10% by mass with respect to the total mass of the treatment liquid.

The content of the organic acid is preferably 0.1% to 50.0% by mass, more preferably 0.5% to 30.0% by mass, and still more preferably 1.0% to 10.0% by mass with respect to the total mass of components in the treatment liquid excluding a solvent.

### <Polymer>

Examples of the polymer include a water-soluble polymer.

The “water-soluble polymer” means a compound having two or more constitutional units linked in a linear or mesh form through a covalent bond, in which a mass of the polymer dissolved in 100 g of water at 20° C. is 0.1 g or more.

Examples of the water-soluble polymer include a polyacrylic acid, a polymethacrylic acid, a polymaleic acid, a polyvinylsulfonic acid, a polyallylsulfonic acid, a polystyrenesulfonic acid, and salts thereof; copolymers of monomers such as styrene, α-methylstyrene, and/or 4-methylstyrene and acid monomers such as a (meth)acrylic acid and/or a maleic acid, and salts thereof; polymers having constitutional units having an aromatic hydrocarbon group obtained by fusing benzenesulfonic acid and/or naphthalenesulfonic acid, and the like with formalin; polyglycerin; vinyl-based synthetic polymers such as polyvinyl alcohol, polyoxyethylene, polyvinylpyrrolidone, polyvinylpyridine, polyacrylamide, polyvinyl formamide, polyethyleneimine, polyvinyloxazoline, polyvinylimidazole, and polyallylamine; and modified products of natural polysaccharides such as hydroxyethyl cellulose, carboxymethyl cellulose, and processed starch.

As the polymer, water-soluble polymers described in paragraphs to of JP2016-171294A can also be used, the content of which is incorporated herein by reference.

A molecular weight (in a case of having a molecular weight distribution, a weight-average molecular weight) of the polymer is preferably 300 or more, more preferably more than 600, still more preferably 1,000 or more, particularly preferably more than 1,000, and most preferably 2,000 or more. The upper limit thereof is preferably 1,500,000 or less and more preferably 1,000,000 or less.

The polymer may be used alone, or two or more types thereof may be used in combination.

A content of the polymer is preferably 0.0001% to 5.00% by mass, more preferably 0.0005% to 1.00% by mass, and still more preferably 0.001% to 0.10% by mass with respect to the total mass of the treatment liquid.

The content of the polymer is preferably 0.1% to 50.0% by mass, more preferably 0.5% to 30.0% by mass, and still more preferably 1.0% to 10.0% by mass with respect to the total mass of components in the treatment liquid excluding a solvent.

### <Polyhydroxy Compound Having Molecular Weight of 500 or More>

As the polyhydroxy compound, compounds exemplified in paragraphs [0101] and [0102] of WO2022/014287A can be used, the contents of which are incorporated herein by reference.

### <Oxidant>

Examples of the oxidant include a peroxide, a persulfide (for example, a monopersulfide or a dipersulfide), a percarbonate, an acid thereof, and a salt thereof.

Examples of the oxidant also include an oxidative halide (a periodic acid such as iodic acid, metaperiodic acid, and orthoperiodic acid, and salts thereof), a perboric acid, a perboric acid salt, a cerium compound, and a ferricyanide (potassium ferricyanide or the like).

A content of the oxidant is preferably 0.0001% to 5.00% by mass, more preferably 0.0005% to 1.00% by mass, and still more preferably 0.001% to 0.10% by mass with respect to the total mass of the treatment liquid.

The content of the oxidant is preferably 0.1% to 50.0% by mass, more preferably 0.5% to 30.0% by mass, and still more preferably 1.0% to 10.0% by mass with respect to the total mass of components in the treatment liquid excluding a solvent.

### [Physical Properties of Treatment Liquid]

Hereinafter, properties of the treatment liquid will be described in detail.

<pH>

The treatment liquid may be either basic or acidic.

From the viewpoint that the effect of the present invention is more excellent, the pH of the treatment liquid is preferably 8.0 to 14.0, more preferably 9.0 to 14.0, still more preferably 10.0 to 14.0, and particularly preferably 10.0 to 13.5.

The pH of the treatment liquid can be measured by a method based on JIS Z 8802-1984 using a known pH meter. A measurement temperature of the pH is 25° C.

### <Metal Content>

A content (measured as ion concentration) of all metals (for example, metal elements of Fe, Co, Na, Cu, Mg, Mn, Li, A1, Cr, Ni, Zn, Sn, and Ag) contained as impurities in the treatment liquid is preferably 5 ppm by mass or less, and more preferably 1 ppm by mass or less. It is assumed that, in manufacturing of a cutting-edge semiconductor element, a treatment liquid having even higher purity is required, and thus the metal content thereof is more preferably a value lower than 1 mass ppm, that is, lower than a value of mass ppb order, particularly preferably 100 mass ppb or less, and most preferably less than 10 mass ppb. The lower limit thereof is preferably 0.

Examples of a method for reducing the metal content include performing a purifying treatment such as distillation and filtration using an ion exchange resin or a filter at a stage of raw materials used in the production of the treatment liquid or a stage after the production of the treatment liquid.

Other examples of the method for reducing the metal content include using a container with less elution of impurities, which will be described later, as a container that accommodates the raw material or the produced treatment liquid. In addition, other examples thereof include lining an interior wall of the pipe with a fluororesin to prevent the elution of metal components from a pipe or the like during the production of the treatment liquid.

### <Coarse Particles>

The treatment liquid may contain coarse particles, but it is preferable that a content thereof is preferably low.

The coarse particles mean particles having a diameter (particle size) of 0.03 μm or more, in a case where a shape of the particles is regarded as a sphere.

The coarse particles contained in the treatment liquid correspond to, for example, particles such as rubbish, dust, organic solid, and inorganic solid, which are contained as impurities in raw materials, and particles such as rubbish, dust, organic solid, and inorganic solid, which are brought in as contaminants during the preparation of the treatment liquid, in which those particles are finally present as particles without being dissolved in the treatment liquid.

The content of the coarse particles in the treatment liquid, in terms of content of particles having a particle size of 0.1 μm or more, is preferably 10,000 or less and more preferably 5,000 or less per 1 mL of the treatment liquid. A lower limit thereof is preferably 0 or more, and more preferably 0.01 or more per milliliter of the treatment liquid.

The content of the coarse particles present in the treatment liquid can be measured in a liquid phase by using a commercially available measuring device in a light scattering type liquid particle measuring method using a laser as a light source.

Examples of a method for removing the coarse particles include a purification treatment such as filtering, which will be described later.

### [Production Method]

The treatment liquid can be produced by a known method. Hereinafter, a production method of the treatment liquid will be described in detail.

### [Liquid Preparation Step]

The treatment liquid can be produced, for example, by mixing the above-described components.

Examples of the method for preparing the treatment liquid include a method in which the purine compound, the amine compound, and, as necessary, an optional component are sequentially charged into a container containing purified pure water, the mixture is stirred and mixed, and a pH adjuster is added as necessary to adjust the pH of the mixed solution, thereby preparing the treatment liquid. In addition, in a case where the water and the respective components are charged into the container, the water and the respective components may be charged at once, or may be charged in a divided manner a plurality of times.

As a stirring device and a stirring method used for preparing the treatment liquid, a known device may be used as a stirrer or a disperser. Examples of a stirrer include an industrial mixer, a portable stirrer, a mechanical stirrer, and a magnetic stirrer. Examples of the disperser include an industrial disperser, a homogenizer, an ultrasonic disperser, and a beads mill.

The mixing of the respective components in the step of preparing the treatment liquid, a refining treatment described later, and storage of the produced treatment liquid are preferably performed at 40° C. or lower, and more preferably performed at 30° C. or lower. The lower limit thereof is preferably 5° C. or higher and more preferably 10° C. or higher. By preparing, treating, and/or storing the treatment liquid in the above-described temperature range, stable performance can be maintained for a long period of time.

### <Purification>

It is preferable to subject any one or more of the raw materials for preparing the treatment liquid to a purification treatment in advance. Examples of the purification treatment include known methods such as distillation, ion exchange, and filtration (filtering).

Regarding a degree of purification, it is preferable to carry out the purification treatment until the purity of the raw material is 99% by mass or more, and it is more preferable to carry out the purification treatment until the purity of the raw material is 99.9% by mass or more. The upper limit thereof is preferably 99.9999% by mass or less.

Examples of a method of the purification treatment include a method of passing the raw material through an ion exchange resin, a reverse osmosis membrane (RO membrane), or the like, distillation of a raw material, and filtering described later.

The purification treatment may be carried out by combining a plurality of the above-described purification methods. For example, the raw materials are subjected to primary purification by passing through an RO membrane, and then subjected to secondary purification by passing through a purification device consisting of a cation-exchange resin, an anion-exchange resin, or a mixed-bed type ion exchange resin.

In addition, the purification treatment may be performed a plurality of times.

The filter which is used for filtering is not particularly limited as long as it has been used in application for filtering and the like in the related art. Examples thereof include filters formed of fluororesins such as polytetrafluoroethylene (PTFE) and tetrafluoroethylene perfluoroalkyl vinyl ether copolymer (PFA), polyamide-based resins such as nylon, polyolefin resins (including those with a high density and a ultra-high molecular weight) such as polyethylene and polypropylene (PP), or the like. Among these materials, a material selected from the group consisting of polyethylene, polypropylene (including a high-density polypropylene), a fluororesin (including PTFE and PFA), and a polyamide-based resin (including nylon) is preferable; and a filter of the fluororesin is more preferable. By carrying out filtering of the raw materials using a filter formed of these materials, high-polarity foreign matters which are likely to cause defects can be more effectively removed.

### <Container>

The treatment liquid (including an aspect of a diluted treatment liquid described later) can be added in any container to be stored and transported as long as problems such as corrosiveness do not arise.

In application for a semiconductor, the container is preferably a container which has a high degree of cleanliness inside the container and in which the elution of impurities from an interior wall of an accommodating portion of the container into the each liquid is suppressed. Examples of such a container include various containers commercially available as a container for a semiconductor treatment liquid, such as “CLEAN BOTTLE” series manufactured by AICELLO MILIM CHEMICAL Co., Ltd. and “PURE BOTTLE” manufactured by Kodama Plastics Co., Ltd., but the container is not limited thereto.

In addition, as the container, containers exemplified in paragraphs to of WO2022/004217A can also be used, the contents of which are incorporated herein by reference.

The inside of these containers is preferably cleaned before filling the treatment liquid. With regard to a liquid used for the cleaning, the amount of metal impurities in the liquid is preferably reduced. The treatment liquid may be bottled in a container such as a gallon bottle and a coated bottle after the production, and then may be transported and stored.

In order to prevent changes in the components of the treatment liquid during the storage, the inside of the container may be purged with an inert gas (such as nitrogen and argon) having a purity of 99.99995% by volume or more. In particular, a gas with a low moisture content is preferable. In addition, during the transportation and the storage, the temperature may be normal temperature or may be controlled in a range of −20° C. to 20° C. to prevent deterioration.

### <Clean Room>

It is preferable that handlings including production of the treatment liquid, opening and cleaning of the container, and filling of the treatment liquid, treatment analysis, and measurements are all performed in a clean room. It is preferable that the clean room meets the 14644-1 clean room standard. It is preferable that the clean room satisfies any one of International Organization for Standardization (ISO) Class 1, ISO Class 2, ISO Class 3, or ISO Class 4, it is more preferable that the clean room satisfies ISO Class 1 or ISO Class 2, and it is still more preferable that the clean room satisfies ISO Class 1.

### [Dilution Step]

The above-described treatment liquid may be used for treating an object as a diluted treatment liquid after undergoing a dilution step of diluting the treatment liquid using a diluent such as water.

The diluted treatment liquid is also an aspect of the treatment liquid according to the embodiment of the present invention as long as it satisfies the requirements of the present invention.

It is preferable to subject the diluent which is used in the dilution step to a purification treatment in advance. In addition, it is more preferable that the diluted treatment liquid obtained in the dilution step is subjected to a purification treatment.

Examples of the purification treatment include the ion component reducing treatment using the ion exchange resin, the RO membrane, or the like, and the foreign matter removal using filtering, which are described as the purification treatment for the treatment liquid above, and it is preferable to carry out any one of these treatments.

A dilution rate of the treatment liquid in the dilution step may be appropriately adjusted depending on the type and content of each component and the object to be treated, but the ratio (dilution rate) of the diluted treatment liquid to the treatment liquid before the dilution is preferably 10 to 10,000 times, more preferably 20 to 3,000 times, and still more preferably 50 to 1,000 times in terms of mass ratio or volume ratio (volume ratio at 23° C.).

In addition, from the viewpoint of more excellent cleanability, the treatment liquid is preferably diluted with water.

A change in pH before and after the dilution (a difference between the pH of the treatment liquid before the dilution and the pH of the diluted treatment liquid) is preferably 2.0 or less, more preferably 1.8 or less, and still more preferably 1.5 or less.

It is preferable that the pH of the treatment liquid before the dilution and the pH of the diluted treatment liquid are each in the above-described suitable aspect.

A specific method for the dilution step of diluting the treatment liquid may be performed according to the step of preparing the treatment liquid described above. A stirring device and a stirring method used in the dilution step may also be performed using the known stirring device described in the step of preparing the treatment liquid above.

### [Use Application]

The treatment liquid according to the embodiment of the present invention can be used for various materials used in the manufacturing of a semiconductor. Hereinafter, the object of the treatment liquid according to the embodiment of the present invention will be described in detail.

The above-described treatment liquid can be used, for example, for treating an insulating film, a resist, an antireflection film, an etching residue, an ashing residue, and the like, which are present on a substrate. The above-described treatment liquid is preferably used as a cleaning liquid, and more preferably used in a cleaning step of cleaning an object to be treated (particularly, a semiconductor substrate) which has been subjected to a CMP treatment.

As described above, in a case where the treatment liquid is used, the treatment liquid may be used as a diluted treatment liquid obtained by diluting the treatment liquid.

### [Object]

Examples of the object to be treated with the treatment liquid include an object containing a metal; and a semiconductor substrate containing a metal is preferable.

In a case where the semiconductor substrate contains a metal, for example, the metal may be present on any of front and back surfaces, side surfaces, inside of a groove, and the like of the semiconductor substrate. In addition, in a case where the semiconductor substrate contains a metal, the metal includes not only a case in which the metal is directly present on the surface of the semiconductor substrate, but also a case in which the metal is present on the semiconductor substrate through another layer.

Examples of the metal include at least one metal M selected from the group consisting of copper (Cu), cobalt (Co), ruthenium (Ru), aluminum (Al), tungsten (W), titanium (Ti), tantalum (Ta), chromium (Cr), hafnium (Hf), osmium (Os), platinum (Pt), nickel (Ni), manganese (Mn), iron (Fe), zirconium (Zr), molybdenum (Mo), palladium (Pd), lanthanum (La), and iridium (Ir); and Cu, Co, or Ru is preferable, and Cu or Co is more preferable.

That is, the object is preferably an object containing at least one metal selected from the group consisting of Cu and Co.

The metal may be a substance containing metal (metal atom), and examples thereof include a simple substance of the metal M and an alloy containing the metal M.

The object to be treated with the treatment liquid may have, for example, a semiconductor substrate, a metal wire film, a barrier metal, and an insulating film.

Examples of the wafer constituting the semiconductor substrate include a wafer consisting of a silicon-based material, such as a silicon (Si) wafer, a silicon carbide (SIC) wafer, and a silicon-including resin-based wafer (glass epoxy wafer), a gallium phosphorus (GaP) wafer, a gallium arsenic (GaAs) wafer, and an indium phosphorus (InP) wafer.

Examples of the silicon wafer include an n-type silicon wafer in which a silicon wafer is doped with a pentavalent atom (for example, phosphorus (P), arsenic (As), antimony (Sb), or the like) and a p-type silicon wafer in which a silicon wafer is doped with a trivalent atom (for example, boron (B), gallium (Ga), or the like). Examples of the silicon of the silicon wafer include amorphous silicon, single crystal silicon, polycrystalline silicon, and polysilicon.

Among these, a wafer consisting of a silicon-based material, such as a silicon wafer, a silicon carbide wafer, and a resin-based wafer (a glass epoxy wafer) including silicon, is preferable.

Examples of the insulating film include a silicon oxide film (for example, a silicon dioxide (SiO₂) film, a tetraethyl orthosilicate (Si(OC₂H₅)₄) film (a TEOS film), a silicon nitride film (for example, silicon nitride (Si₃N₄), and silicon nitride carbide (SiNC)), and a low-dielectric-constant (Low-k) film (for example, a carbon-doped silicon oxide (SiOC) film and a silicon carbide (SiC) film); and a low-dielectric-constant (Low-k) film is preferable.

As the metal wire film, a copper-containing film, a cobalt-containing film, or a ruthenium-containing film is preferable.

Examples of the copper-containing film include a wire film consisting of only metal copper (copper wire film), and a wire film made of an alloy consisting of metal copper and another metal (a copper alloy wire film).

Specific examples of the copper alloy wire film include a wire film made of an alloy consisting of one or more metals selected from Al, Ti, Cr, Mn, Ta, and W, and copper. More specific examples of the copper alloy wire film include a copper-aluminum alloy wire film (CuAl alloy wire film), a copper-titanium alloy wire film (CuTi alloy wire film), a copper-chromium alloy wire film (CuCr alloy wire film), a copper-manganese alloy wire film (CuMn alloy wire film), a copper-tantalum alloy wire film (CuTa alloy wire film), and a copper-tungsten alloy wire film (CuW alloy wire film).

Examples of the cobalt-containing film include a metal film consisting of only metal cobalt (cobalt metal film) and a metal film made of an alloy consisting of metal cobalt and another metal (cobalt alloy metal film).

Examples of the cobalt alloy metal film include a metal film made of an alloy consisting of one or more metals selected from Ti, Cr, Fe, Ni, Mo, Pd, Ta, and W, and cobalt. More specific examples of the cobalt alloy metal film include a cobalt-titanium alloy metal film (a CoTi alloy metal film), a cobalt-chromium alloy metal film (a CoCr alloy metal film), a cobalt-iron alloy metal film (a CoFe alloy metal film), a cobalt-nickel alloy metal film (a CoNi alloy metal film), a cobalt-molybdenum alloy metal film (a CoMo alloy metal film), a cobalt-palladium alloy metal film (a CoPd alloy metal film), a cobalt-tantalum alloy metal film (a CoTa alloy metal film), and a cobalt-tungsten alloy metal film (a CoW alloy metal film).

The treatment liquid is useful for a substrate having the cobalt-containing film. Among the cobalt-containing films, the cobalt metal film is usually used as a wire film, and the cobalt alloy metal film is usually used as a barrier metal.

Examples of the ruthenium-containing film include a metal film consisting of only metal ruthenium (ruthenium metal film) and a metal film made of an alloy consisting of metal ruthenium and another metal (ruthenium alloy metal film). The ruthenium-containing film is usually used as a barrier metal.

A method of forming the insulating film, the copper-containing film, the cobalt-containing film, and the ruthenium-containing film on the wafer constituting the semiconductor substrate is not particularly limited as long as it is a method generally carried out in this field.

Examples of the method of forming the insulating film include a method in which the wafer constituting the semiconductor substrate is subjected to a heat treatment in the presence of oxygen gas to form a silicon oxide film, and then a gas of silane and ammonia is introduced thereto to form a silicon nitride film by a chemical vapor deposition (CVD) method.

Examples of the method of forming the copper-containing film, the cobalt-containing film, and the ruthenium-containing film include a method of forming a circuit on a wafer having the above-described insulating film by a known method such as a resist, and then forming the copper-containing film, the cobalt-containing film, and the ruthenium-containing film by a method such as plating and a CVD method.

<Object which has been Subjected to CMP Treatment>

As the object in a case of using the treatment liquid for cleaning, an object (particularly, a semiconductor substrate) which has been subjected to the CMP treatment is preferable; and an object containing at least one metal selected from the group consisting of Cu and Co, which has been subjected to the CMP treatment, is more preferable.

The CMP treatment is a treatment in which a surface of the semiconductor substrate having the metal wire film, the barrier metal, and the insulating film is flattened by a combined action of a chemical action and a mechanical polishing using a polishing slurry including polishing fine particles (abrasive grains).

A surface of the object which has been subjected to the CMP treatment may have impurities remaining thereon, such as abrasive grains (for example, silica and alumina) used in the CMP treatment, a polished metal wire film, and metal impurities (metal residue) derived from the barrier metal. In addition, organic impurities derived from a CMP treatment liquid used in the CMP treatment may remain. For example, since these impurities may cause a short-circuit between wiring lines and deteriorate electrical characteristics of the semiconductor substrate, the semiconductor substrate which has been subjected to the CMP treatment is subjected to a cleaning treatment for removing these impurities from the surface.

Specific examples of the object which has been subjected to the CMP treatment include substrates which have been subjected to the CMP treatment, described in Journal of the Japan Society for Precision Engineering, Vol. 84, No. 3, 2018, but the present invention is not limited thereto.

<Object which has been Subjected to Buffing>

An object (particularly, a semiconductor substrate) in a case of using the treatment liquid for cleaning may be subjected to a buffing treatment after being subjected to the CMP treatment.

The buffing treatment is a treatment of reducing impurities on the surface of the semiconductor substrate using a polishing pad. Specifically, the surface of the semiconductor substrate which has been subjected to the CMP treatment is brought into contact with the polishing pad, and the semiconductor substrate and the polishing pad are relatively slid while supplying a composition for buffing to a contact portion. As a result, impurities on the surface of the semiconductor substrate are removed by a frictional force of the polishing pad and a chemical action of a composition for buffing.

As the composition for buffing, a known composition for buffing can be appropriately used depending on the type of the semiconductor substrate, and the type and amount of the impurities to be removed. Examples of components contained in the composition for buffing include a water-soluble polymer such as polyvinyl alcohol, water as a dispersion medium, and an acid such as nitric acid.

In addition, as an embodiment of the buffing treatment, it is also preferable to use a treatment liquid as the composition for buffing.

A polishing device, polishing conditions, and the like, which are used in the buffing treatment, can be appropriately selected from known devices and conditions according to the type of the semiconductor substrate, the object to be removed, and the like. Examples of the buffing treatment include treatments described in paragraphs to of WO2017/169539A, the contents of which are incorporated herein by reference.

### [Method of Using Treatment Liquid]

The treatment liquid can be used by a known method. Hereinafter, a method of using the treatment liquid will be described in detail.

### [Treatment Step]

Examples of the method of using the treatment liquid include a treatment method for an object, which includes a step of bringing the object into contact with the treatment liquid. Hereinafter, the step of bringing the object into contact with the treatment liquid is also referred to as “contact step”.

The method of bringing the object into contact with the treatment liquid is not particularly limited; and examples thereof include a method of immersing the object in the treatment liquid contained in a tank, a method of spraying the treatment liquid onto the object, a method of flowing the treatment liquid onto the object, and a combination thereof. The above-described method may be appropriately selected depending on the purpose.

In addition, the above-described method may appropriately adopt a method usually performed in the field. For example, scrub cleaning in which a cleaning member such as a brush is physically brought into contact with a surface of the object while supplying the treatment liquid to remove residues and the like, spinning (dropping) cleaning in which the treatment liquid is dropped while rotating the object, or the like may be used. From the viewpoint that impurities remaining on a surface of the object to be treated can be further reduced, it is preferable that the object to be treated immersed in the treatment liquid is subjected to an ultrasonic treatment.

The contact between the object and the treatment liquid in the contact step may be carried out only once or twice or more. In a case of carrying out the contact twice or more, the same method may be repeated or different methods may be combined.

A method for the contact step may be a single-wafer method or a batch method.

The single-wafer method is generally a method of treating the objects one by one, and the batch method is generally a method of treating a plurality of the objects at the same time.

A temperature of the treatment liquid is not particularly limited as long as it is a temperature usually used in this field. Generally, the cleaning is carried out at room temperature (approximately 25° C.), but any temperature can be selected in order to improve the cleanability and suppress the damage resistance to a member. For example, the temperature of the treatment liquid is preferably 10° C. to 60° C., and more preferably 15° C. to 50° C.

A contact time between the object and the treatment liquid can be appropriately changed depending on the type and content of each component contained in the treatment liquid, and the use target and purpose of the treatment liquid. The contact time is practically 10 to 120 seconds, preferably 20 to 90 seconds and more preferably 30 to 60 seconds.

A supply amount (supply rate) of the treatment liquid is preferably 50 to 5,000 mL/min, and more preferably 500 to 2,000 mL/min.

In the contact step, a mechanical stirring method may be used in order to further improve the cleaning ability of the treatment liquid.

Examples of the mechanical stirring method include a method of circulating the treatment liquid on the object, a method of flowing or spraying the treatment liquid on the object, and a method of stirring the treatment liquid with ultrasonic wave or megasonic wave.

In addition, after the contact step, a step of bringing the object into contact with a rinsing liquid (hereinafter, also referred to as “rinsing step”) may be performed. By performing the rinsing step, the object to be treated, obtained in the contact step, is washed with a rinsing liquid, and the residues can be efficiently removed.

The rinsing step is preferably a step which is performed continuously subsequently after the cleaning step of the object to be treated, which is performed continuously after the cleaning step of the semiconductor substrate. The rinsing step may be performed using the above-described mechanical stirring method.

Examples of the rinsing liquid include water (preferably, DI water), methanol, ethanol, isopropyl alcohol (IPA), N-methylpyrrolidinone, γ-butyrolactone, dimethyl sulfoxide, ethyl lactate, and propylene glycol monomethyl ether acetate. In addition, an aqueous rinsing liquid having a pH of more than 8.0 (aqueous ammonium hydroxide which has been diluted, or the like) may be used.

As the method in which the rinsing liquid is brought into contact with the object to be treated, the method in which the treatment liquid is brought into contact with the object to be treated can be similarly applied.

A contact time between the object to be treated and the rinsing liquid can be appropriately changed depending on the type and content of each component contained in the treatment liquid, and the use target and purpose of the treatment liquid. The contact time is practically 10 to 120 seconds, preferably 20 to 90 seconds and more preferably 30 to 60 seconds.

A drying step of drying the object to be treated may be performed after the above-described rinsing step.

Examples of the drying method include a spin drying method, a method of flowing a dry gas onto the object to be treated, a method of heating a substrate by a heating unit such as a hot plate and an infrared lamp, a Marangoni drying method, a Rotagoni drying method, an IPA drying method, and a method of combining any of these methods.

### [Manufacturing Method of Electronic Device]

The above-described treatment method for an object to be treated can be suitably applied to a manufacturing process of an electronic device.

The above-described treatment method may be performed in combination before or after other steps performed on a substrate. The above-described treatment method may be incorporated into other steps while performing the treatment method, or the above-described treatment method may be incorporated into the other steps.

Examples of the other steps include a step of forming each structure such as a metal wire, a gate structure, a source structure, a drain structure, an insulating film, a ferromagnetic layer, and a non-magnetic layer (for example, layer formation, etching, chemical mechanical polishing, modification, or the like), a resist forming step, an exposure step and a removal step, a heat treatment step, a cleaning step, and an examination step.

The above-described treatment method may be performed at any stage among the back-end process (BEOL: back end of the line), the middle process (MOL: middle of the line), and the front-end process (FEOL: front end of the line); and it is preferable that the treatment method be performed in a front-end process or a middle process.

### Examples

Hereinafter, the present invention will be described in more detail with reference to Examples.

The materials, the amounts of the materials to be used, the proportions, and the like shown in the Examples below may be modified as appropriate as long as the modifications do not depart from the spirit of the present invention. Therefore, the scope of the present invention is construed as being limited to Examples shown below.

In the following Examples, a pH of the treatment liquid was measured at 25° C. using a pH meter (manufactured by HORIBA, Ltd., model “F-74”) in accordance with JIS Z 8802-1984.

In addition, in production of treatment liquids of Examples and Comparative Examples, all of handling of a container, and production, filling, storage, and analytical measurement of the treatment liquids were performed in a clean room satisfying a level of ISO Class 2 or lower.

### [Raw Materials of Treatment Liquid]

The following compounds were used to produce a treatment liquid. As various components used in Examples, those all classified into a semiconductor grade or a high-purity grade equivalent thereto were used.

### [Purine Compound]

Adenine (corresponding to the compound represented by Formula (C5))
6-Benzyladenine (corresponding to the compound represented by Formula (C5))
Kinetin (corresponding to the compound represented by Formula (C5))
Dimethyladenine (corresponding to the compound represented by Formula (C5))
Methyladenine (corresponding to the compound represented by Formula (C5))
Adenosine (corresponding to the compound represented by Formula (C5))
Xanthine (corresponding to the compound represented by Formula (C7))
Hypoxanthine (corresponding to the compound represented by Formula (C6))

### [Amine Compound]

DMAMP: 2-(dimethylamino)-2-methyl-1-propanol (pKa=14.8, molecular weight:

117)
DEAE: 2-(diethylamino) ethanol (pKa=14.8, molecular weight: 117)
2-(Diisopropylamino) ethanol (pKa=14.8, molecular weight: 145)
1-Methyl-2-piperidinemethanol (pKa=14.8, molecular weight: 129)
HOPEMP: 4-hydroxy-1,2,2,6,6-pentamethylpiperidine (pKa=14.5, molecular weight: 171)
1-Piperidineethanol (pKa=14.8, molecular weight: 129)
DMAE: 2-(dimethylamino) ethanol (pKa=14.8, molecular weight: 89)
1-Methyl-3-piperidinemethanol (pKa=14.8, molecular weight: 129)
1-Methyl-3-pyrrolidinone (pKa=14.5, molecular weight: 101)
t-BDEA: N-tert-butyldiethanolamine (pKa=14.8, molecular weight: 161)
Tetramethyl-1,6-diaminohexane (pKa=10.1, molecular weight: 172)
Tetramethyl-1,3-diaminopropane (pKa=8.6, molecular weight: 130)
Pentamethyldipropylene triamine (pKa=10.0, molecular weight: 201)
DABCO: 1,4-diazabicyclo[2.2.2]octane (pKa=1.7, molecular weight: 112)
3-Hydroxy-1-methylpiperidine (pKa=14.6, molecular weight: 115)
PMDETA: N,N,N′,N″,N″-pentamethyldiethylenetriamine (pKa=9.6, molecular weight: 173)
2-(Dimethylamino)ethylamine (pKa=10.0, molecular weight: 88)
1,2-Bis(methylamino) ethane (pKa=6.7, molecular weight: 88)
Diisopropanolamine (pKa=14.6, molecular weight: 133)
AMP: 2-amino-2-methyl-1-propanol (pKa=14.8, molecular weight: 89)

In a case where the above-described amine compound exhibits a plurality of pKa's, the largest pKa value is shown above.

### [Other Compounds]

Succinic acid
Tartaric acid
Maleic acid
Polyacrylic acid (Mw=4,000)
EGBE: ethylene glycol mono-n-butyl ether
IPA: Isopropyl alcohol

In the treatment liquid, the remaining component (remainder) other than components specified as the components of the treatment liquid in the tables was ultrapure water.

### [Production of Treatment Liquid]

Next, a production method of a treatment liquid will be described with reference to Example 1.

Adenine, DMAMP, and PMDETA were added to ultrapure water in an amount such that the finally obtained treatment liquid had the formulation shown in the tables below. The obtained mixed solution was sufficiently stirred to obtain a treatment liquid of Example 1.

According to the production method of Example 1, a treatment liquid of each of Examples or each of Comparative Examples, having the formulation shown in the tables below, was produced.

[Evaluation 1 of Treatment Liquid: Semiconductor Substrate after CMP]

The obtained treatment liquid was evaluated for anticorrosion properties and cleanability. Hereinafter, the evaluation method will be described.

### [Evaluation of Anticorrosion Properties]

Using the treatment liquid produced by the above-described method, anticorrosion properties against Cu and Co were evaluated.

A Cu or Co wafer having a size of 2×2 cm was prepared.

The above-described wafer was placed in a container filled with the treatment liquid of each of Examples or each of Comparative Examples, and subjected to an immersion treatment at room temperature (25° C.) for 30 minutes. Thereafter, contents of Cu and Co in the immersed treatment liquid were measured by Agilent 8800 triple quadrupole ICP-MS (for semiconductor analysis, option #200), and an etching rate was determined.

The anticorrosion properties of the treatment liquid were evaluated according to the following evaluation standard. As the etching rate was lower, the anticorrosion properties were better.
A: less than 0.4 Å/min
B: 0.4 Å/min or more and less than 0.6 Å/min
C: 0.6 Å/min or more and less than 0.8 Å/min
D: 0.8 Å/min or more

### [Evaluation of Cleanability]

The cleanability was evaluated in a case where a semiconductor substrate subjected to a CMP treatment was cleaned using the treatment liquid produced by the above-described method.

Using FREX300S-II (polishing device, manufactured by EBARA CORPORATION), a wafer (diameter: 12 inches) having a Cu film or a Co film on a surface was polished under conditions in which a polishing liquid 1 was used as a polishing liquid, an in-plane average value of a polishing pressure was 105 hPa, a supply rate of the polishing liquid was 200 mL/min, and a polishing time was 30 seconds. Next, the wafer subjected to the above-described polishing treatment was further polished under conditions in which a polishing liquid 2 was used as a polishing liquid, an in-plane average value of a polishing pressure was 70 hPa, a supply rate of the polishing liquid was 200 mL/min, and a polishing time was 60 seconds.

The obtained wafer subjected to the CMP treatment was subjected to scrub cleaning for 1 minute using a sample of the treatment liquid adjusted to room temperature (23° C.), and then subjected to a drying treatment.

Formulations of the polishing liquid 1 and the polishing liquid 2 described above were as follows.
Polishing liquid 1 (pH: 7.0)
   Colloidal silica (PL3, manufactured by FUSO CHEMICAL CO., LTD.)
      0.1% by mass
   Glycine 1.0% by mass
   3-Amino-1,2,4-triazole 0.2% by mass
   Benzotriazole (BTA) 30 ppm by mass
   Hydrogen peroxide 1.0% by mass
   pH adjuster (ammonia and nitric acid)
   Water remainder
Polishing liquid 2 (pH: 10.5)
   Colloidal silica (PL3, manufactured by FUSO CHEMICAL CO., LTD.)
   BTA 0.2% by mass
   Hydrogen peroxide 1.0% by mass
   pH adjuster (potassium hydroxide and nitric acid)
   Water remainder

Next, a defect detection device (ComPlus-II, manufactured by AMAT) was used to measure the number of detections of signal intensities corresponding to defects having a length of more than 0.1 μm on the obtained polished surface of the wafer. Thereafter, each defect was observed with a scanning electron microscope (SEM), and the constituent elements were specified as a measurement target with an energy dispersive X-ray spectroscopy (EDX) device as necessary.

From the above, the number of defects based on organic residues (residues containing an organic substance as a main component) on the polished surface of the wafer was determined.

The cleanability of the treatment liquid was evaluated according to the following evaluation standard. As the number of defects detected on the polished surface of the wafer was smaller, the cleanability was better.
A: number of target defects was 20 or less.
B: number of target defects was more than 20 and 40 or less.
C: number of target defects was more than 40 and 60 or less.
D: number of target defects was more than 60.

### [Result]

In the tables, the column of “Content (% by mass” indicates the content (% by mass) of each component with respect to the total mass of the treatment liquid.

In the column of “Formula” of the tables, a case where the amine compound described in the left column of the column of “Formula” was the compound represented by Formula (A1) is indicated as “A1”, and a case where the amine compound described in the left column of the column of “Formula” was the compound represented by Formula (A2) is indicated as “A2”.

In the column of “Molecular weight” of the tables, a case where the molecular weight of the amine compound described in the left column of the column of “Molecular weight” was 100 to 160 is indicated as “A”, and other case is indicated as “B”.

In the column of “Carbon atoms” of the tables, a case where the number of carbon atoms of the amine compound described in the left column of the column of “Carbon atoms” was 6 to 9 is indicated as “A”, and other case is indicated as “B”.

In the column of “Cyclic structure” of the tables, a case where the amine compound described in the left column of the column of “Cyclic structure” had a cyclic structure is indicated as “A”, and a case where the amine compound did not have a cyclic structure is indicated as “B”.

In the tables, the numerical value in the column of “(I)/(II)” indicates the mass ratio of the content (I) of the purine compound to the content (II) of the amine compound (content (I) of purine compound/content (II) of amine compound).

In the tables, the numerical value in the column of pKa is an acid dissociation constant calculated using “ChemDraw” (registered trademark, manufactured by CambridgeSoft Corporation, software version: 20.1.1.125).

In a case where the above-described amine compound exhibited a plurality of pKa's, the largest pKa value is shown above.

In the tables, the numerical value in the column of pH indicates the pH of the treatment liquid at 25° C., which was measured by the above-described pH meter.

TABLE 1

| | Treatment liquid | | | | | | | | |
|---|---|---|---|---|---|---|---|---|---|
| | Purine compound (I) | | Amine compound (II) | | | | | | |
| | | Content | | | Molecular | Carbon | Cyclic | | Content |
| | Type | (% by mass) | Amine compound A | Formula | weight | atoms | structure | pKa | (% by mass) |
| Example 1 | Adenine | 0.00033 | DMAMP | A1 | A | A | A | 14.8 | 0.039 |
| Example 2 | Adenine | 0.00033 | DEAE | A1 | A | A | A | 14.8 | 0.039 |
| Example 3 | Adenine | 0.00033 | 2-(Diisopropylamino)ethanol | A1 | A | A | A | 14.8 | 0.039 |
| Example 4 | Adenine | 0.00033 | 1-Methyl-2-piperidinemethanol | A1 | A | A | B | 14.8 | 0.039 |
| Example 5 | Adenine | 0.00033 | HOPEMP | A1 | B | B | A | 14.5 | 0.039 |
| Example 6 | Adenine | 0.00033 | 1-Piperidineethanol | A1 | A | A | B | 14.8 | 0.039 |
| Example 7 | Adenine | 0.00033 | DMAE | A1 | B | B | A | 14.8 | 0.039 |
| Example 8 | Adenine | 0.00033 | 1-Methyl-3-piperidinemethanol | A1 | A | A | B | 14.8 | 0.039 |
| Example 9 | Adenine | 0.00033 | 1-Methyl-3-pyrrolidinone | A1 | A | B | B | 14.5 | 0.039 |
| Example 10 | Adenine | 0.00033 | t-BDEA | A1 | B | A | A | 14.8 | 0.039 |
| Example 11 | Adenine | 0.00033 | Tetramethyl-1,6-diaminohexane | A2 | B | B | A | 10.1 | 0.039 |
| Example 12 | Adenine | 0.00033 | Tetramethyl-1,3-diaminopropane | A2 | A | A | A | 8.6 | 0.039 |
| Example 13 | Adenine | 0.00033 | Pentamethyldipropylene | A2 | B | B | A | 10.0 | 0.039 |
| | | | triamine | | | | | | |
| Example 14 | Adenine | 0.00033 | DABCO | A2 | A | A | B | 1.7 | 0.039 |
| Example 15 | Adenine | 0.00033 | 3-Hydroxy-1-methylpiperidine | A1 | A | A | B | 14.6 | 0.039 |
| Example 16 | Adenine | 0.00033 | 3-Hydroxy-1-methylpiperidine | A1 | A | A | B | 14.6 | 0.039 |
| Example 17 | Adenine | 0.00033 | 3-Hydroxy-1-methylpiperidine | A1 | A | A | B | 14.6 | 0.039 |
| Example 18 | Adenine | 0.00033 | 3-Hydroxy-1-methylpiperidine | A1 | A | A | B | 14.6 | 0.039 |
| Example 19 | 6-Benzyladenine | 0.00033 | 3-Hydroxy-1-methylpiperidine | A1 | A | A | B | 14.6 | 0.039 |
| Example 20 | Kinetin | 0.00033 | 3-Hydroxy-1-methylpiperidine | A1 | A | A | B | 14.6 | 0.039 |
| Example 21 | Dimethyladenine | 0.00033 | 3-Hydroxy-1-methylpiperidine | A1 | A | A | B | 14.6 | 0.039 |
| Example 22 | Methyladenine | 0.00033 | 3-Hydroxy-1-methylpiperidine | A1 | A | A | B | 14.6 | 0.039 |
| Example 23 | Xanthine | 0.00033 | 3-Hydroxy-1-methylpiperidine | A1 | A | A | B | 14.6 | 0.039 |
| Example 24 | Adenosine | 0.00033 | 3-Hydroxy-1-methylpiperidine | A1 | A | A | B | 14.6 | 0.039 |
| Example 25 | Xanthine | 0.00033 | 3-Hydroxy-1-methylpiperidine | A1 | A | A | B | 14.6 | 0.039 |
| | adenosine | 0.00033 | | | | | | | |
| Example 26 | Hypoxanthine | 0.00033 | 3-Hydroxy-1-methylpiperidine | A1 | A | A | B | 14.6 | 0.039 |
| Example 27 | Hypoxanthine | 0.00033 | 3-Hydroxy-1-methylpiperidine | A1 | A | A | B | 14.6 | 0.039 |
| Example 28 | Hypoxanthine | 0.00033 | 3-Hydroxy-1-methylpiperidine | A1 | A | A | B | 14.6 | 0.039 |

| | Treatment liquid | | | | | | | Object to be treated | | | |
|---|---|---|---|---|---|---|---|---|---|---|---|
| | Amine compound (II) | | | | Other additives | | | | | Anticorrosion | |
| | | | Content | | | Content | | Cleanability | | properties | |
| | Amine compound B | pKa | (% by mass) | I/II | Type | (% by mass) | pH | Cu | Co | Cu | Co |
| Example 1 | PMDETA | 9.6 | 0.017 | 0.006 | — | — | 11.0 | A | A | A | A |
| Example 2 | PMDETA | 9.6 | 0.017 | 0.006 | — | — | 10.8 | A | A | A | A |
| Example 3 | PMDETA | 9.6 | 0.017 | 0.006 | — | — | 10.9 | A | A | A | A |
| Example 4 | PMDETA | 9.6 | 0.017 | 0.006 | — | — | 10.7 | A | A | A | B |
| Example 5 | PMDETA | 9.6 | 0.017 | 0.006 | — | — | 10.7 | A | A | A | B |
| Example 6 | PMDETA | 9.6 | 0.017 | 0.006 | — | — | 10.7 | A | A | A | B |
| Example 7 | PMDETA | 9.6 | 0.017 | 0.006 | — | — | 10.5 | A | A | A | C |
| Example 8 | PMDETA | 9.6 | 0.017 | 0.006 | — | — | 10.5 | A | A | A | C |
| Example 9 | PMDETA | 9.6 | 0.017 | 0.006 | — | — | 10.5 | A | A | A | C |
| Example 10 | PMDETA | 9.6 | 0.017 | 0.006 | — | — | 10.3 | A | A | A | C |
| Example 11 | PMDETA | 9.6 | 0.017 | 0.006 | — | — | 11.0 | B | B | B | B |
| Example 12 | PMDETA | 9.6 | 0.017 | 0.006 | — | — | 10.8 | B | B | B | B |
| Example 13 | PMDETA | 9.6 | 0.017 | 0.006 | — | — | 10.7 | B | B | B | B |
| Example 14 | PMDETA | 9.6 | 0.017 | 0.006 | — | — | 10.5 | A | A | B | C |
| Example 15 | PMDETA | 9.6 | 0.017 | 0.006 | — | — | 10.3 | A | A | B | C |
| Example 16 | 2-(Dimethylamino)ethylamine | 10.0 | 0.017 | 0.006 | — | — | 10.2 | B | B | B | C |
| Example 17 | 1,2-Bis(methylamino)ethane | 6.7 | 0.017 | 0.006 | — | — | 10.2 | B | B | B | C |
| Example 18 | Diisopropanolamine | 14.6 | 0.017 | 0.006 | — | — | 10.2 | C | C | B | C |
| Example 19 | Diisopropanolamine | 14.6 | 0.017 | 0.006 | — | — | 10.2 | C | C | B | C |
| Example 20 | Diisopropanolamine | 14.6 | 0.017 | 0.006 | — | — | 10.2 | C | C | B | C |
| Example 21 | Diisopropanolamine | 14.6 | 0.017 | 0.006 | — | — | 10.2 | C | C | B | C |
| Example 22 | Diisopropanolamine | 14.6 | 0.017 | 0.006 | — | — | 10.2 | C | C | B | C |
| Example 23 | Diisopropanolamine | 14.6 | 0.017 | 0.006 | — | — | 10.2 | C | C | C | B |
| Example 24 | Diisopropanolamine | 14.6 | 0.017 | 0.006 | — | — | 10.2 | C | C | C | B |
| Example 25 | Diisopropanolamine | 14.6 | 0.017 | 0.012 | — | — | 10.2 | C | C | C | B |
| Example 26 | Diisopropanolamine | 14.6 | 0.017 | 0.006 | — | — | 10.2 | C | C | C | C |
| Example 27 | Diisopropanolamine | 14.6 | 0.0086 | 0.007 | — | — | 10.2 | C | C | C | C |
| Example 28 | Diisopropanolamine | 14.6 | 0.024 | 0.005 | — | — | 10.2 | C | C | C | C |

TABLE 2

| | Treatment liquid | | | | | | | | |
|---|---|---|---|---|---|---|---|---|---|
| | Purine compound (I) | | Amine compound (II) | | | | | | |
| | | Content | | | Molecular | Carbon | Cyclic | | Content |
| | Type | (% by mass) | Amine compound A | Formula | weight | atoms | structure | pKa | (% by mass) |
| Example 29 | Hypoxanthine | 0.00033 | 3-Hydroxy-1-methylpiperidine | A1 | A | A | B | 14.6 | 0.057 |
| Example 30 | Hypoxanthine | 0.00033 | 3-Hydroxy-1-methylpiperidine | A1 | A | A | B | 14.6 | 0.017 |
| Example 31 | Hypoxanthine | 0.00003 | 3-Hydroxy-1-methylpiperidine | A1 | A | A | B | 14.6 | 0.039 |
| Example 32 | Hypoxanthine | 0.0019 | 3-Hydroxy-1-methylpiperidine | A1 | A | A | B | 14.6 | 0.039 |
| Example 33 | Hypoxanthine | 0.017 | 3-Hydroxy-1-methylpiperidine | A1 | A | A | B | 14.6 | 1.94 |
| Example 34 | Adenine | 0.00003 | DMAMP | A1 | A | A | A | 14.8 | 0.039 |
| Example 35 | Adenine | 0.0019 | DMAMP | A1 | A | A | A | 14.8 | 0.039 |
| Example 36 | Adenine | 0.00033 | DMAMP | A1 | A | A | A | 14.8 | 0.057 |
| Example 37 | Adenine | 0.00033 | DMAMP | A1 | A | A | A | 14.8 | 0.017 |
| Example 38 | Adenine | 0.00033 | DMAMP | A1 | A | A | A | 14.8 | 0.039 |
| Example 39 | Adenine | 0.00033 | DMAMP | A1 | A | A | A | 14.8 | 0.039 |
| Example 40 | Adenine | 0.00033 | 3-Hydroxy-1-methylpiperidine | A1 | A | A | B | 14.6 | 0.039 |
| Example 41 | Adenine | 0.00033 | DMAMP | A1 | A | A | A | 14.8 | 0.039 |
| Example 42 | Adenine | 0.00033 | DMAMP | A1 | A | A | A | 14.8 | 0.039 |
| Example 43 | Adenine | 0.00033 | DMAMP | A1 | A | A | A | 14.8 | 0.039 |
| Example 44 | Adenine | 0.00033 | DMAMP | A1 | A | A | A | 14.8 | 0.039 |
| Example 45 | Adenine | 0.00033 | DMAMP | A1 | A | A | A | 14.8 | 0.039 |
| Example 46 | Adenine | 0.00033 | DMAMP | A1 | A | A | A | 14.8 | 0.039 |
| Example 47 | Adenine | 0.00033 | DMAMP | A1 | A | A | A | 14.8 | 0.039 |
| Comparative | — | — | 3-Hydroxy-1-methylpiperidine | A1 | A | A | B | 14.6 | 0.039 |
| Example 1 | | | | | | | | | |
| Comparative | Hypoxanthine | 0.00033 | — | — | — | — | — | — | — |
| Example 2 | | | | | | | | | |
| Comparative | Hypoxanthine | 0.00033 | 3-Hydroxy-1-methylpiperidine | A1 | A | A | B | 14.6 | 0.039 |
| Example 3 | | | | | | | | | |
| Comparative | Hypoxanthine | 0.000004 | 3-Hydroxy-1-methylpiperidine | A1 | A | A | B | 14.6 | 0.039 |
| Example 4 | | | | | | | | | |
| Comparative | Hypoxanthine | 0.007 | 3-Hydroxy-1-methylpiperidine | A1 | A | A | B | 14.6 | 0.039 |
| Example 5 | | | | | | | | | |

| | Treatment liquid | | | | | | | Object to be treated | | | |
|---|---|---|---|---|---|---|---|---|---|---|---|
| | Amine compound (II) | | | | Other additives | | | | | Anticorrosion | |
| | | | Content | | | Content | | Cleanability | | properties | |
| | Amine compound B | pKa | (% by mass) | I/II | Type | (% by mass) | PH | Cu | Co | Cu | Co |
| Example 29 | Diisopropanolamine | 14.6 | 0.017 | 0.004 | — | — | 10.2 | C | C | C | C |
| Example 30 | Diisopropanolamine | 14.6 | 0.017 | 0.010 | — | — | 10.2 | C | C | C | C |
| Example 31 | Diisopropanolamine | 14.6 | 0.017 | 0.0005 | — | — | 10.2 | C | C | C | C |
| Example 32 | Diisopropanolamine | 14.6 | 0.017 | 0.034 | — | — | 10.3 | C | C | C | C |
| Example 33 | Diisopropanolamine | 14.6 | 0.84 | 0.006 | — | — | 11.1 | C | C | C | C |
| Example 34 | PMDETA | 9.6 | 0.017 | 0.0005 | — | — | 11.0 | A | A | A | A |
| Example 35 | PMDETA | 9.6 | 0.017 | 0.034 | — | — | 11.0 | A | A | A | A |
| Example 36 | PMDETA | 9.6 | 0.017 | 0.004 | — | — | 11.0 | A | A | A | A |
| Example 37 | PMDETA | 9.6 | 0.017 | 0.010 | — | — | 11.0 | A | A | A | A |
| Example 38 | PMDETA | 9.6 | 0.0086 | 0.007 | — | — | 11.0 | A | A | A | A |
| Example 39 | PMDETA | 9.6 | 0.024 | 0.005 | — | — | 1.0 | A | A | A | A |
| Example 40 | 2-(Dimethylamino)ethylamine | 10.0 | 0.0084 | 0.006 | — | — | 10.2 | B | B | B | C |
| | 1,2-Bis(methylamino)ethane | 6.7 | 0.0084 | | | | | | | | |
| Example 41 | PMDETA | 9.6 | 0.024 | 0.005 | Succinic | 0.001 | 11.0 | A | A | A | A |
| | | | | | acid | | | | | | |
| Example 42 | PMDETA | 9.6 | 0.024 | 0.005 | Tartaric | 0.001 | 11.0 | A | A | A | A |
| | | | | | acid | | | | | | |
| Example 43 | PMDETA | 9.6 | 0.024 | 0.005 | Maleic | 0.001 | 11.0 | A | A | A | A |
| | | | | | acid | | | | | | |
| Example 44 | PMDETA | 9.6 | 0.024 | 0.005 | Polyacrylic | 0.001 | 11.0 | A | A | A | A |
| | | | | | acid | | | | | | |
| Example 45 | PMDETA | 9.6 | 0.024 | 0.005 | EGBE | 0.010 | 11.0 | A | A | A | A |
| Example 46 | PMDETA | 9.6 | 0.024 | 0.005 | EGBE | 0.005 | 11.0 | A | A | A | A |
| | | | | | IPA | 0.005 | | | | | |
| Example 47 | PMDETA | 9.6 | 0.024 | 0.005 | — | — | 11.0 | A | A | A | A |
| | AMP | 14.8 | 0.001 | | | | | | | | |
| Comparative | Diisopropanolamine | 14.6 | 0.017 | — | — | — | 10.3 | C | C | D | D |
| Example 1 | | | | | | | | | | | |
| Comparative | Diisopropanolamine | 14.6 | 0.017 | 0.020 | — | — | 10.0 | D | D | D | D |
| Example 2 | | | | | | | | | | | |
| Comparative | — | — | — | 0.009 | — | — | 10.1 | D | D | C | C |
| Example 3 | | | | | | | | | | | |
| Comparative | Diisopropanolamine | 14.6 | 0.017 | 0.00007 | — | — | 10.3 | C | C | D | D |
| Example 4 | | | | | | | | | | | |
| Comparative | Diisopropanolamine | 14.6 | 0.017 | 0.126 | — | — | 10.2 | D | D | C | C |
| Example 5 | | | | | | | | | | | |

From the above tables, it was found that the treatment liquid according to the embodiment of the present invention had excellent anticorrosion properties against Cu and Co, and also had excellent cleanability for organic residues on the surface of an object to be treated.

From the comparison of Examples 1 to 13, it was found that, in a case where the amine compound A was the compound represented by Formula (A1), the cleanability was more excellent.

From the comparison of Examples 1 to 15 (particularly, the comparison of Examples 11 to 14 with other Examples), it was found that, in a case where the pKa of the amine compound A was 8.0 to 20.0 (preferably 11.0 to 16.0), the anticorrosion properties against Cu were more excellent.

From the comparison of Examples 1 to 10 (particularly, the comparison of Examples 5, 7, and 10 with other Examples), it was confirmed that, in a case where the molecular weight of the amine compound A was 100 to 160, the anticorrosion properties against Co were more excellent.

From the comparison of Examples 1 to 10 (particularly, the comparison of Examples 5 and 9 with other Examples), it was found that, in a case where the number of carbon atoms of the amine compound A was 6 to 9, the anticorrosion properties against Co were more excellent.

From the comparison of Examples 1 to 10 and 15 (in particular, the comparison of Examples 4, 6, and 8 with other Examples), it was found that, in a case where the amine compound did not have a cyclic structure, the effect of the present invention was more excellent.

From the comparison of Examples 18 to 26, it was found that, in a case where the purine compound included at least one selected from the group consisting of adenine, 6-benzyladenine, kinetin, dimethyladenine, methyladenine, xanthine, and adenosine, the anticorrosion properties were more excellent.

From the comparison of Examples 15 to 18, it was found that, in a case where the amine compound B had two or more nitrogen atoms, the cleanability was more excellent; and in a case where the amine compound B had three or more nitrogen atoms, the cleanability was further excellent.

From the comparison of Examples 15 to 18, it was found that, in a case where the amine compound B was a tertiary amine compound, the cleanability was more excellent.

From the comparison of Examples 26 and 33, it was found that the effect of the present invention was excellent even in a case where the concentration of the treatment liquid was different.

Furthermore, the treatment liquid described in Example 33 was diluted 50 times in terms of mass ratio with ultrapure water as a diluent. In a case where the same evaluations as in Example 33 were performed according to the above-described evaluation procedures using the obtained diluted treatment liquid, the same evaluation results as in Example 33 were obtained.

[Evaluation 2 of Treatment Liquid: Semiconductor Substrate after Buffing Cleaning]

A wafer (diameter: 12 inches) having a Cu film or a Co film on a surface was polished according to the procedure described in [Evaluation of cleanability] of [Evaluation 1 of treatment liquid: semiconductor substrate after CMP].

The polished surface of the wafer subjected to the CMP treatment was subjected to buffing cleaning under the following conditions using FREX300S-II (polishing device, manufactured by EBARA CORPORATION).
Table rotation speed: 80 rpm
Head rotation speed: 78 rpm
In-plane average value of polishing pressure: 138 hPa
Polishing pad: IC1400 manufactured by Rodel-Nitta
Cleaning liquid: treatment liquid used in Example 1
Supply rate of cleaning liquid: 250 mL/min
Polishing time: 20 seconds

The obtained wafer subjected to the buffing cleaning was subjected to scrub cleaning for 1 minute using the treatment liquid used in Example 1, adjusted to room temperature (23° C.), and then subjected to a drying treatment. Thereafter, as a result of obtaining the number of defects based on organic residues on the polished surface of the wafer according to the procedure described in the evaluation of the cleanability of the evaluation 1, the same evaluation results as in Example 1 were obtained.

Even in a case where the treatment liquids used in Examples 2 to 47 were used instead of the above-described treatment liquid used in Example 1, the same evaluation results as the results of each of Examples shown in Tables 1 and 2 described above were obtained.

Furthermore, even in a case where a diluted treatment liquid obtained by diluting the treatment liquid used in Example 33 50 times in terms of mass ratio was used instead of the above-described treatment liquid used in Example 1, the same evaluation results as in Example 33 were obtained.

What is claimed is:

1. A semiconductor treatment liquid comprising:
a purine compound; and
an amine compound,
wherein the purine compound includes at least one selected from the group consisting of purine and a purine derivative,
the amine compound includes one amine compound A and one or two or more amine compounds B different from the amine compound A,
the amine compound A is a tertiary amine compound, and
a mass ratio of a content of the purine compound to a content of the amine compound is 0.0001 to 0.1.

2. The semiconductor treatment liquid according to claim 1,
wherein the amine compound A is one selected from the group consisting of a compound represented by Formula (A1) and a compound represented by Formula (A2), 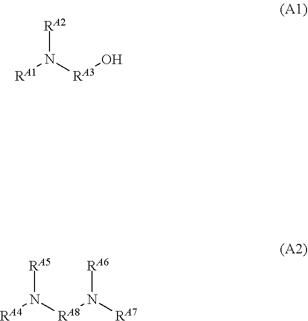
in Formula (A1), R^{A1} and R^{A2} each independently represent an alkyl group which may have a substituent,
R^{A3} represents an alkylene group which may have a substituent, and
two of R^{A1} to R^{A3} may be bonded to each other through a single bond or a divalent linking group to form a ring,
in Formula (A2), R^{A4} to R^{A7} each independently represent an alkyl group which may have a substituent, two of R^{A4} to R^{A7} may be bonded to each other through a single bond or a divalent linking group to form a ring,
R^{A8} represents an alkylene group which may have a hydroxy group or may have a linking group represented by —NR^{Ax}—, and R^{Ax} represents a hydrogen atom or an alkyl group.

3. The semiconductor treatment liquid according to claim 1,
wherein a pH is 10.0 to 14.0.

4. The semiconductor treatment liquid according to claim 1,
wherein the purine compound includes at least one selected from the group consisting of a compound represented by Formula (C5) and a compound represented by Formula (C7), 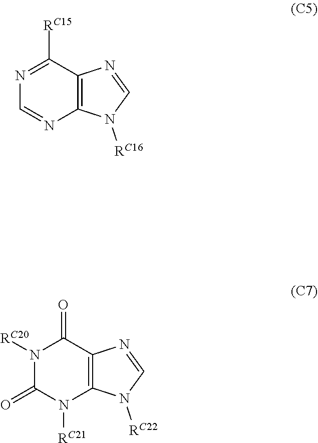
in Formula (C5), R^{C15} and R^{C16} each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent,
in Formula (C7), R^{C20} to R^{C22} each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent.

5. The semiconductor treatment liquid according to claim 1,
wherein at least one of the one or two or more amine compounds B is a tertiary amine compound.

6. The semiconductor treatment liquid according to claim 1,
wherein at least one of the one or two or more amine compounds B is an amine compound having two or more nitrogen atoms.

7. The semiconductor treatment liquid according to claim 1,
wherein at least one of the one or two or more amine compounds B is an amine compound having three or more nitrogen atoms.

8. The semiconductor treatment liquid according to claim 1,
wherein a pKa of the amine compound A is 11.0 to 16.0.

9. The semiconductor treatment liquid according to claim 1,
wherein a molecular weight of the amine compound A is 100 to 160.

10. The semiconductor treatment liquid according to claim 1,
wherein the amine compound A has 6 to 9 carbon atoms.

11. The semiconductor treatment liquid according to claim 1,
wherein the purine compound includes at least one selected from the group consisting of adenine, 6-benzyladenine, kinetin, dimethyladenine, methyladenine, xanthine, and adenosine.

12. The semiconductor treatment liquid according to claim 1,
wherein the semiconductor treatment liquid is used as a cleaning liquid.

13. The semiconductor treatment liquid according to claim 1,
wherein the semiconductor treatment liquid is used for an object which has been subjected to a chemical mechanical polishing treatment.

14. The semiconductor treatment liquid according to claim 1,
wherein the semiconductor treatment liquid is used for an object containing at least one metal selected from the group consisting of Cu and Co.

15. The semiconductor treatment liquid according to claim 1,
wherein the semiconductor treatment liquid is used for an object containing at least one metal selected from the group consisting of Cu and Co, which has been subjected to a chemical mechanical polishing treatment.

16. A treatment method for an object to be treated, comprising:
a step of bringing an object containing at least one metal selected from the group consisting of Cu and Co, which has been subjected to a chemical mechanical polishing treatment, into contact with the semiconductor treatment liquid according to claim 1.

17. A manufacturing method of an electronic device, comprising:
the treatment method for an object to be treated according to claim 16.

18. The semiconductor treatment liquid according to claim 2,
wherein a pH is 10.0 to 14.0.

19. The semiconductor treatment liquid according to claim 2,
wherein the purine compound includes at least one selected from the group consisting of a compound represented by Formula (C5) and a compound represented by Formula (C7), 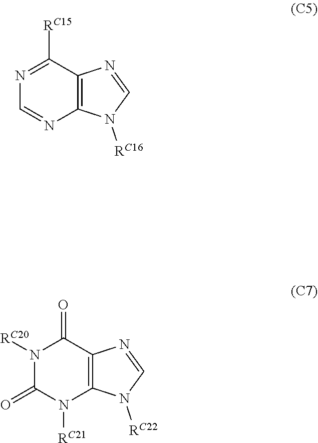
in Formula (C5), R^{C15} and R^{C16} each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent,
in Formula (C7), R^{C20} to R^{C22} each independently represent a hydrogen atom, an alkyl group which may have a substituent, an amino group which may have a substituent, a thiol group, a hydroxy group, a halogen atom, a sugar group which may have a substituent, or a polyoxyalkylene group-containing group which may have a substituent.

20. The semiconductor treatment liquid according to claim 2,
wherein at least one of the one or two or more amine compounds B is a tertiary amine compound.
